(19) United States
(12) Patent Application Publication
(10) Pub. No.: US 2017/0223449 A1
(43) Pub. Date: Aug. 3, 2017

(54) ELECTRONIC DEVICE, EARPHONE, AND ELECTRONIC DEVICE SYSTEM

(71) Applicant: KYOCERA CORPORATION, Kyoto (JP)

(72) Inventor: Yasuhiro MIKI, lkoma-shi (JP)

(21) Appl. No.: 15/491,673

(22) Filed: Apr. 19, 2017

Related U.S. Application Data
(63) Continuation of application No. PCT/JP2015/079435, filed on Oct. 19, 2015.

(30) Foreign Application Priority Data
Oct. 22, 2014 (JP) 2014-215253

(51) Int. Cl. H04R 3/00; H04R 1/10; H03F 3/183; H01R 24/58; H03F 3/45; H04R 1/08; H04R 17/00

(52) U.S. Cl. CPC H04R 3/00; H04R 1/08; H04R 1/1016; H04R 17/00; H01R 24/58; H03F 3/45475; H03F 3/183; H01R 2107/00

(57) ABSTRACT

A first terminal of a five-electrode plug is configured to be connected to an input terminal of a first electromagnetic speaker. A second terminal of the five-electrode plug is configured to be connected to an input terminal of a second electromagnetic speaker. A fourth terminal of the five-electrode plug is configured to be connected to a ground terminal of the first electromagnetic speaker, a ground terminal of the second electromagnetic speaker, and a ground terminal of a microphone. A fifth terminal of the five-electrode plug is configured to be connected to an output terminal of the microphone.

### CROSS-REFERENCE TO RELATED APPLICATION

The present application is a continuation based on PCT Application No. PCT/JP2015/079435 filed on Oct. 19, 2015, which claims the benefit of Japanese Application No. 2014-215253 filed on Oct. 22, 2014. PCT Application No. PCT/JP2015/079435 is entitled “Electronic Apparatus, Earphone, and Electronic Apparatus System,” and Japanese Application No. 2014-215253 is entitled “Electronic Device, Earphone, and Electronic Device System.” The content of which is incorporated by reference herein in the entirety.

### FIELD

The present disclosure relates to an electronic device, an earphone, and an electronic device system.

### BACKGROUND

An apparatus which can identify which of a plurality of types of plugs has been inserted in an earphone jack has conventionally been known.

For example, a portable telephone representing one example of background art includes an earphone jack for five electrodes commonly used for a four-electrode plug and a five-electrode plug. The four-electrode plug transmits a microphone signal, a left audio signal, a right audio signal, and a ground voltage, and the five-electrode plug transmits a PTT switch signal, a microphone signal, a left audio signal, a right audio signal, and a ground voltage.

When a plug is inserted, a tone signal is output from a third jack terminal. When a four-electrode plug is inserted here, the tone signal is output from a first jack terminal through a four-electrode earphone as a leakage signal, which is input to a control circuit after it is amplified. When a five-electrode plug is inserted, no leakage signal is output. According to such a configuration, which of the four-electrode plug and the five-electrode plug has been inserted into the plug can be identified.

### SUMMARY

A five-electrode plug earphone in one embodiment includes a first electromagnetic speaker, a second electromagnetic speaker, a microphone, a first processor, and a five-electrode plug. The first electromagnetic speaker includes an input terminal and a ground terminal. The second electromagnetic speaker includes an input terminal and a ground terminal. The microphone includes an output terminal and a ground terminal. The five-electrode plug includes a first terminal, a second terminal, a third terminal, a fourth terminal, and a fifth terminal sequentially from a tip end. The first terminal of the five-electrode plug is configured to be connected to the input terminal of the first electromagnetic speaker. The second terminal of the five-electrode plug is configured to be connected to the input terminal of the second electromagnetic speaker. The third terminal of the five-electrode plug is configured to be connected to the first processor. The fourth terminal of the five-electrode plug is configured to be connected to the ground terminal of the first electromagnetic speaker, the ground terminal of the second electromagnetic speaker, and the ground terminal of the microphone. The fifth terminal of the five-electrode plug is configured to be connected to the output terminal of the microphone.

### BRIEF DESCRIPTION OF THE DRAWINGS

FIG. 1 is a diagram showing a configuration of a portable terminal in an embodiment.

FIG. 2 is a diagram showing a three-electrode plug earphone.

FIG. 3 is a diagram showing a four-electrode plug earphone.

FIG. 4 is a diagram showing a five-electrode plug earphone (piezoelectric).

FIG. 5 is a diagram showing a five-electrode plug earphone (electromagnetic).

FIG. 6 is a diagram showing a detailed configuration of the five-electrode plug earphone (piezoelectric).

FIG. 7 is a diagram showing a detailed configuration of the five-electrode plug earphone (electromagnetic).

FIG. 8 is a diagram showing connection of constituent elements in the three-electrode plug earphone.

FIG. 9 is a diagram showing connection of constituent elements in the four-electrode plug earphone.

FIG. 10 is a diagram showing connection of constituent elements in the five-electrode plug earphone (piezoelectric).

FIG. 11 is a diagram showing connection of constituent elements in the five-electrode plug earphone (electromagnetic).

FIG. 12A is a diagram showing an earphone jack.

FIG. 12B is a diagram showing a five-electrode plug.

FIG. 12C is a diagram showing a four-electrode plug.

FIG. 12D is a diagram showing a three-electrode plug.

FIG. 13 is a diagram showing a configuration associated with transmission and reception of a signal to and from an earphone.

FIG. 14 is a diagram showing connection between the three-electrode plug earphone and constituent elements in the portable terminal when a three-electrode plug is inserted in the earphone jack.

FIG. 15 is a diagram showing connection between the four-electrode plug earphone and constituent elements in the portable terminal when a four-electrode plug is inserted in the earphone jack.

FIG. 16 is a diagram showing connection between the five-electrode plug earphone (piezoelectric) and constituent elements in the portable terminal when a five-electrode plug of the five-electrode plug earphone is inserted in the earphone jack.

FIG. 17 is a diagram showing connection between the five-electrode plug earphone (electromagnetic) and constituent elements in the portable terminal when a five-electrode plug of the five-electrode plug earphone is inserted in the earphone jack.

FIG. 18 is a flowchart showing a procedure for determining insertion and removal of a plug and for identifying a type of a plug.

FIGS. 19A to 19E are diagrams showing a Stage 1, a Stage 2, a Stage 3, a Stage 4, and a Stage 5 in a process of insertion of the five-electrode plug into the earphone jack, respectively.

FIGS. 20A to 20E are diagrams showing a Stage 6, a Stage 7, a Stage 8, a Stage 9, and a Stage 10 in the process of insertion of the five-electrode plug into the earphone jack, respectively.

FIGS. 21A to 21E are diagrams showing a Stage 11, a Stage 12, a Stage 13, a Stage 14, and a Stage 15 in the process of insertion of the five-electrode plug into the earphone jack, respectively.

FIG. 22 is a diagram showing Stage 12 in the process of insertion of the five-electrode plug into the earphone jack when a position of a terminal F of the earphone jack is displaced toward an insertion port.

### DETAILED DESCRIPTION

An embodiment will be described below with reference to the drawings.

In order to operate a piezoelectric element or a processor in an earphone, a voltage should be supplied to the piezoelectric element. A five-electrode earphone jack of a portable telephone representing one example of the background art, however, cannot supply a voltage to the earphone. Such a problem can be solved by the disclosure below.

An electronic device according to an embodiment allows connection of new two types of five-electrode plug earphone in addition to conventional three-electrode and four-electrode plug earphones, and performs a function to determine which plug is connected.

Description will be given below with reference to a portable terminal such as a smartphone as one form of an electronic device.

(Configuration of Portable Terminal)

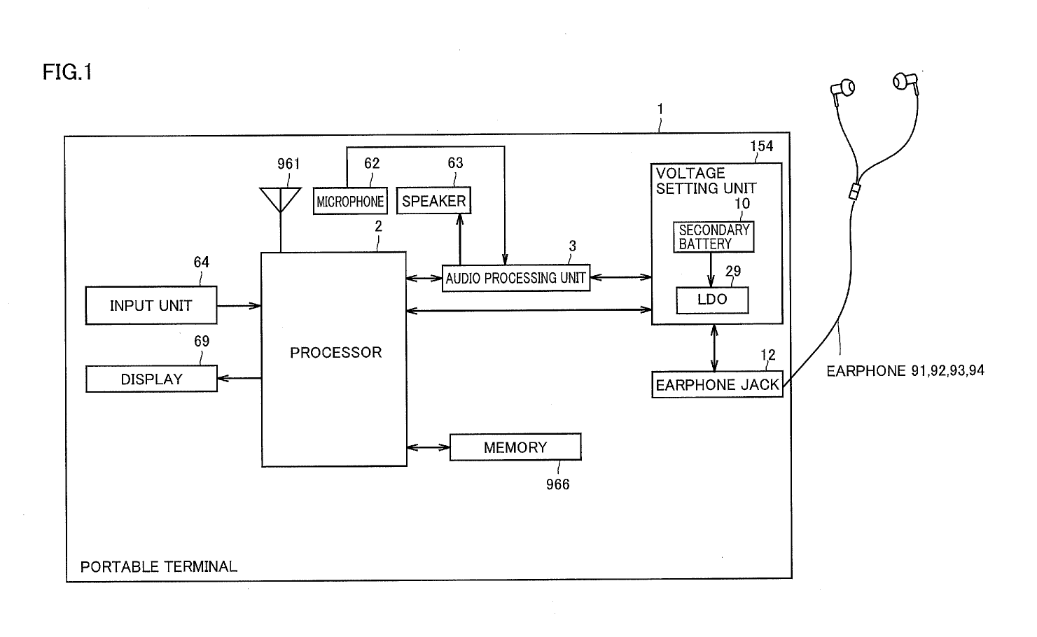

FIG. 1 is a diagram showing a configuration of a portable terminal 1 in an embodiment.

Referring to FIG. 1, portable terminal 1 includes a processor 2, an antenna 961, a condenser microphone 62, a speaker 63, an input unit 64, a display 69, a memory 966, a secondary battery 10, a low dropout regulator (LDO) 29, a voltage setting unit 154, an audio processing unit 3, and an earphone jack 12.

Earphone jack 12 can be connected to a three-electrode plug earphone 91, a four-electrode plug earphone 92, a five-electrode plug earphone 93 (piezoelectric), and a five-electrode plug earphone 94 (electromagnetic). Five-electrode plug earphone 93 (piezoelectric) is an earphone which can output voice and sound by using a piezoelectric element. Five-electrode plug earphone 94 (electromagnetic) is an earphone which can output voice and sound with the use of an electromagnetic speaker.

Voltage setting unit 154 is configured to identify a state of insertion and removal of earphone 91, 92, 93, or 94 into and from earphone jack 12 and a type of the inserted earphone (three-electrode, four-electrode, five-electrode (piezoelectric), or five-electrode (electromagnetic)), details of which will be described later.

Processor 2 is responsible for overall control and can identify a type of an earphone.

In accordance with various embodiments, processor 2 may be implemented as a single integrated circuit (IC) or as multiple communicatively coupled IC's and/or discrete circuits. Processor 2 can be implemented in accordance with various known technologies.

In one embodiment, processor 2 includes one or more circuits or units configurable to perform one or more data computing procedures or processes. For example, processor 2 may include controllers, microprocessors, microcontrollers, application specific integrated circuits (ASICs), digital signal processors, programmable logic devices, field programmable gate arrays, or any combination of these devices or structures, or other known devices and structures, to perform the functions described below.

Antenna 961 can transmit and receive a radio signal to and from a radio base station.

Input unit 64 can accept an input from a user.

In various embodiments, input unit 64 may be implemented using any input technology or device known in the art such as, for example, a QWERTY keyboard, a pointing device (e.g., a mouse), a joy stick, a stylus, a touch screen display panel, a key pad, one or more buttons, etc., or any combination of these technologies.

Display 69 can show an image sent from processor 2.

Memory 966 can store various types of data.

When earphone 91, 92, 93, or 94 is not inserted in earphone jack 12, audio processing unit 3 can output an audio signal to speaker 63 and can receive an audio signal from microphone 62. When three-electrode plug earphone 91 is inserted in earphone jack 12, audio processing unit 3 can output an audio signal to an electromagnetic speaker of three-electrode plug earphone 91. When four-electrode plug earphone 92 is inserted in earphone jack 12, audio processing unit 3 can output an audio signal to an electromagnetic speaker of four-electrode plug earphone 92 and can receive an audio signal from a microphone of four-electrode plug earphone 92. When five-electrode plug earphone 93 (piezoelectric) is inserted in earphone jack 12, audio processing unit 3 can output an audio signal to a piezoelectric element of five-electrode plug earphone 93 (piezoelectric) and can receive an audio signal from a microphone of five-electrode plug earphone 93 (piezoelectric). When five-electrode plug earphone 94 (electromagnetic) is inserted in earphone jack 12, audio processing unit 3 can output an audio signal to an electromagnetic speaker of five-electrode plug earphone 94 (electromagnetic) and can receive an audio signal from a microphone of five-electrode plug earphone 94 (electromagnetic).

Microphone 62 can output an input audio signal to audio processing unit 3.

Speaker 63 can reproduce an audio signal sent from audio processing unit 3.

Secondary battery 10 can supply electric power to constituent elements in portable terminal 1.

LDO 29 can prevent a current not lower than a rated current from flowing from secondary battery 10 to earphone 91, 92, 93, or 94.

Secondary battery 10 can supply electric power to five-electrode plug earphone 93 (piezoelectric) or five-electrode plug earphone 94 (electromagnetic) when five-electrode plug earphone 93 (piezoelectric) or five-electrode plug earphone 94 (electromagnetic) is inserted in earphone jack 12.

(Configuration of Earphone)

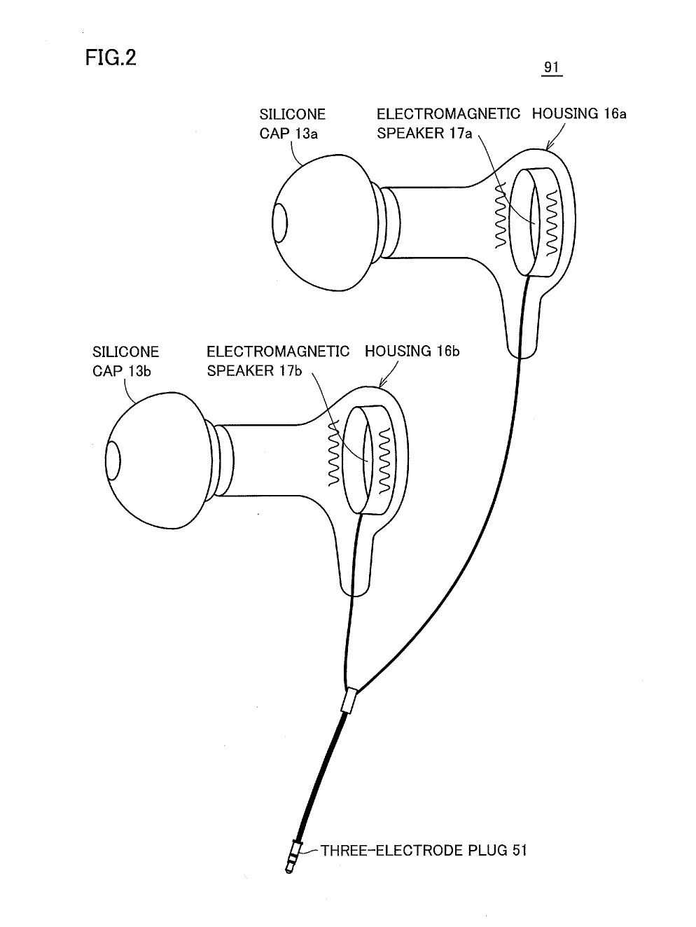

FIG. 2 is a diagram showing three-electrode plug earphone 91.

Three-electrode plug earphone 91 includes a three-electrode plug 51, a silicone cap 13a, a housing 16a, and an electromagnetic speaker 17a for the left ear, and a silicone cap 13b, a housing 16b, and an electromagnetic speaker 17b for the right ear.

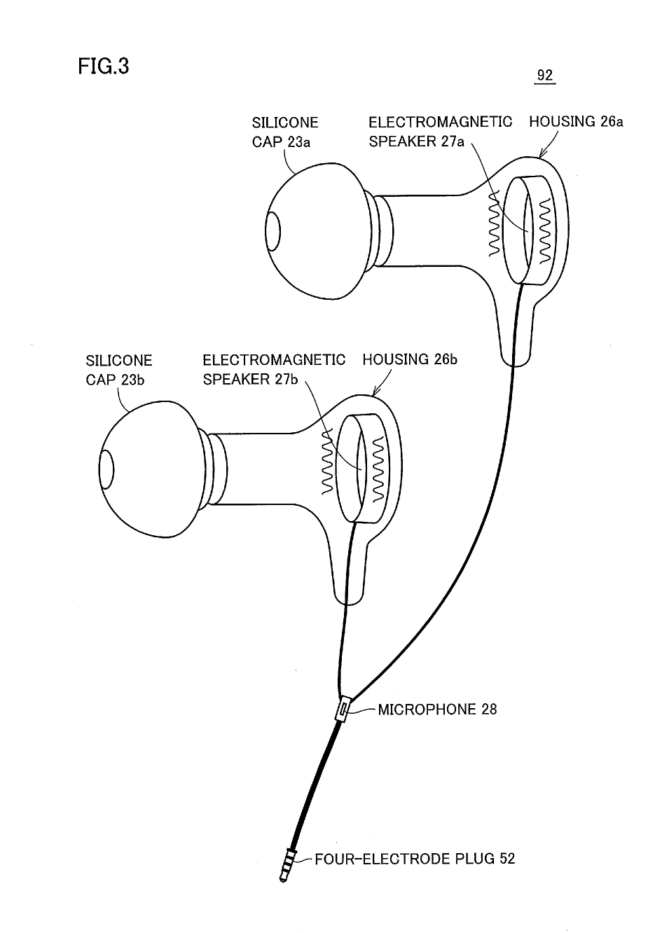

FIG. 3 is a diagram showing four-electrode plug earphone 92.

Four-electrode plug earphone 92 includes a four-electrode plug 52, a microphone 28, a silicone cap 23a, a housing 26a, and an electromagnetic speaker 27a for the left ear, and a silicone cap 23b, a housing 26b, and an electromagnetic speaker 27b for the right ear.

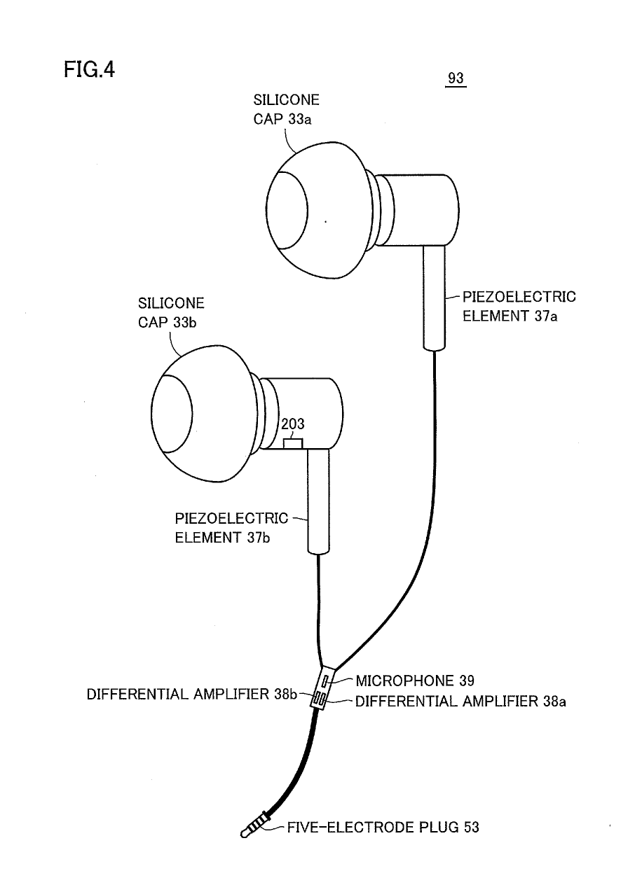

FIG. 4 is a diagram showing five-electrode plug earphone 93 (piezoelectric).

Five-electrode plug earphone 93 (piezoelectric) includes a five-electrode plug 53, a microphone 39, a silicone cap 33a, a differential amplifier 38a, and a piezoelectric element 37a for the left ear, and a silicone cap 33b, a differential amplifier 38b, a pulse sensor 203, and a piezoelectric element 37b for the right ear.

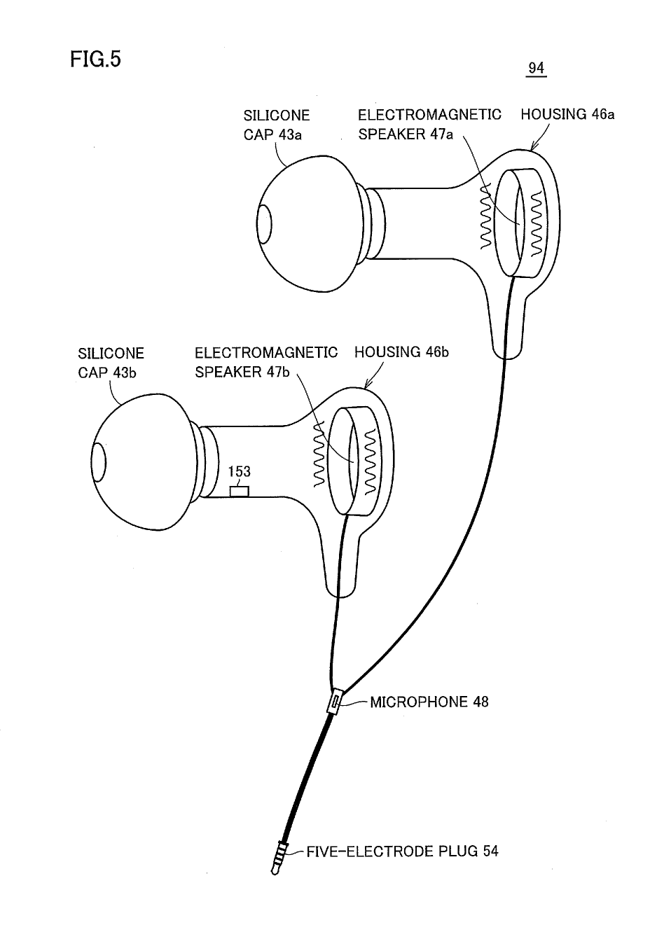

FIG. 5 is a diagram showing five-electrode plug earphone 94 (electromagnetic).

Five-electrode plug earphone 94 (electromagnetic) includes a five-electrode plug 54, a microphone 48, a silicone cap 43a, a housing 46a, and an electromagnetic speaker 47a for the left ear, and a silicone cap 43b, a housing 46b, a pulse sensor 153, and an electromagnetic speaker 47b for the right ear.

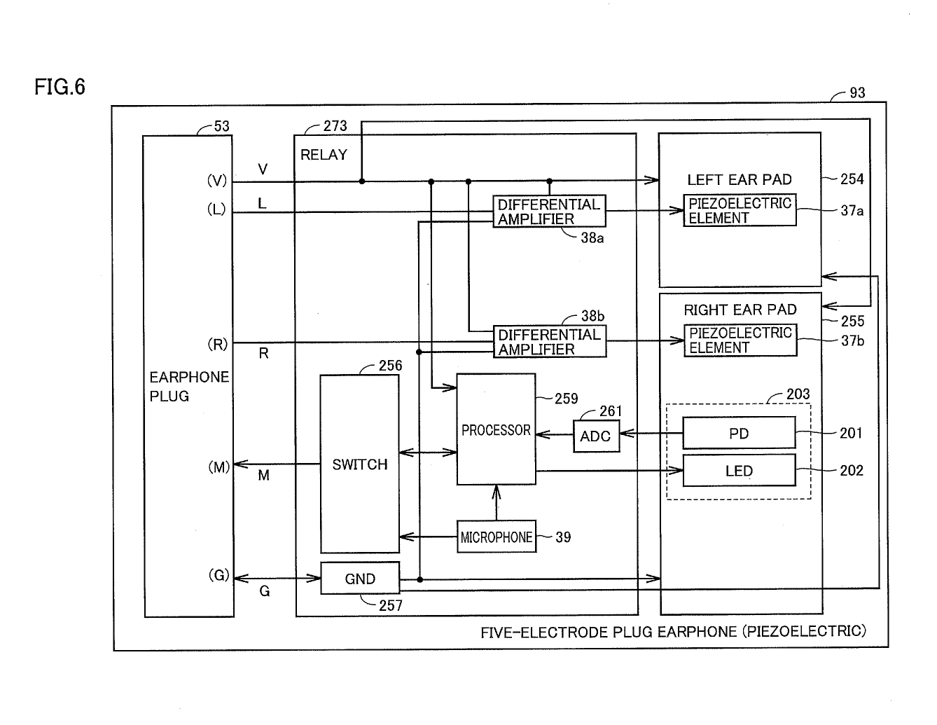

FIG. 6 is a diagram showing a detailed configuration of five-electrode plug earphone 93 (piezoelectric).

Referring to FIG. 6, five-electrode plug earphone 93 (piezoelectric) includes earphone plug 53, a relay 273, a left ear pad 254, and a right ear pad 255.

Earphone plug 53 can be connected to earphone jack 12 of portable terminal 1. Earphone plug 53 includes a power supply terminal (V), a left audio terminal (L), a right audio terminal (R), a microphone terminal (M), and a ground terminal (GND).

Relay 273 includes differential amplifiers 38a, 38b, a switch 256, a processor 259, microphone 39, an ADC 261, and a ground power supply 257.

Left ear pad 254 includes piezoelectric element 37a. Right ear pad 255 includes piezoelectric element 37b and pulse sensor 203. Pulse sensor 203 includes a photodiode (PD) 201 which receives infrared rays and an LED 202 which outputs infrared rays.

Earphone 93 can be attached to an ear of a user such that LED 202 and PD 201 face the skin of the external ear. Transmission waves transmitted from LED 202 can be reflected in the external ear and received as reception waves by PD 201. Blood vessels are located under the skin of the external ear and blood flows therethrough. As the blood vessels constrict in accordance with pulses, an amount of absorption of infrared rays varies. An amount of reflection of infrared rays in a body varies and a period of the reception waves is in synchronization with a period of pulses.

In accordance with various embodiments, processor 259 may be implemented as a single integrated circuit (IC) or as multiple communicatively coupled IC's and/or discrete circuits. Processor 259 can be implemented in accordance with various known technologies.

In one embodiment, processor 25—includes one or more circuits or units configurable to perform one or more data computing procedures or processes. For example, processor 259 may include controllers, microprocessors, microcontrollers, application specific integrated circuits (ASICs), digital signal processors, programmable logic devices, field programmable gate arrays, or any combination of these devices or structures, or other known devices and structures, to perform the functions described below.

Processor 259 can control turn-on of LED 202 and receive a signal from PD 201, and when reception waves received by PD 201 periodically vary, it can calculate pulses based on the period.

Processor 259, PD 201, and LED 202 can operate by receiving a power supply voltage through a signal line V connected to the power supply terminal (V) of earphone plug 53.

Differential amplifier 38a can operate by receiving a power supply voltage through signal line V. Differential amplifier 38a can receive a left audio signal to left ear pad 254 through a signal line L connected to the left audio terminal (L), amplify the left audio signal, and supply the left audio signal to piezoelectric element 37a. Differential amplifier 38b can operate by receiving a power supply voltage through signal line V. Differential amplifier 38b can receive a right audio signal to right ear pad 255 through a signal line R connected to the right audio terminal (R), amplify the right audio signal, and supply the right audio signal to piezoelectric element 37b.

ADC 261 can convert an analog signal output from PD 201 into a digital signal and output the digital signal to processor 259.

Microphone 39 can supply an input audio signal to processor 259 and switch 256.

Switch 256 can select a control signal from processor 259 or an audio signal from microphone 39 and supply the selected signal to earphone plug 53 through a signal line M connected to the microphone terminal (M).

Ground power supply 257 can transmit or receive a ground voltage to or from earphone plug 53 through a signal line G connected to the ground terminal (GND).

Piezoelectric element 37a can oscillate in accordance with magnitude of the left audio signal supplied from differential amplifier 38a. Piezoelectric element 37b can oscillate in accordance with magnitude of the right audio signal supplied from differential amplifier 38b.

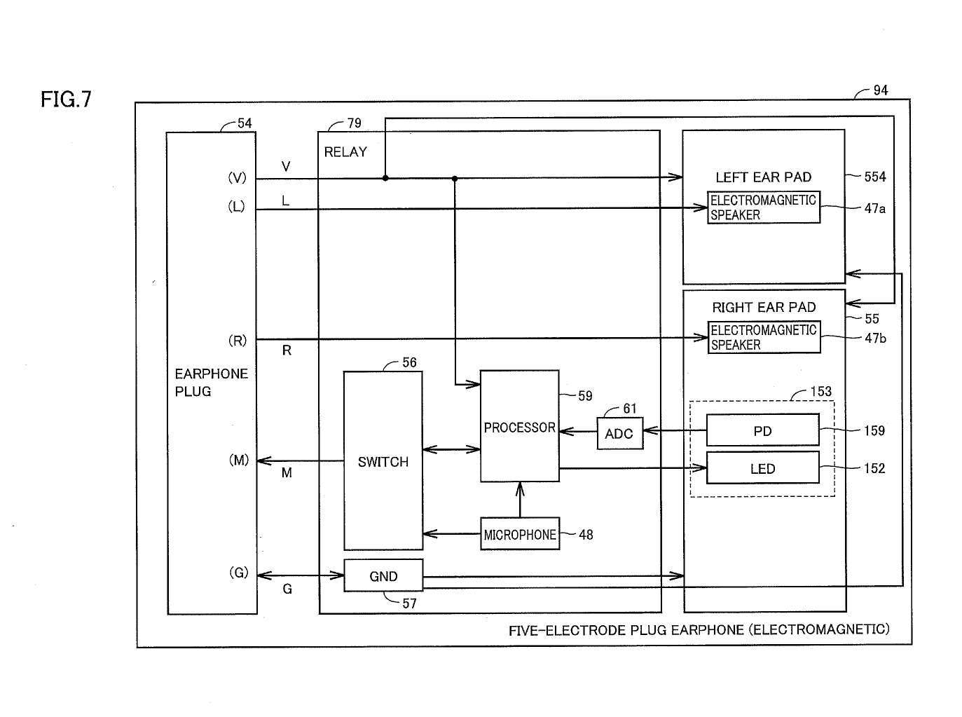

FIG. 7 is a diagram showing a detailed configuration of five-electrode plug earphone 94 (electromagnetic).

Referring to FIG. 7, five-electrode plug earphone 94 (electromagnetic) includes earphone plug 54, a relay 79, a left ear pad 554, and a right ear pad 55.

Earphone plug 54 can be connected to earphone jack 12 of portable terminal 1. Earphone plug 54 includes a power supply terminal (V), a left audio terminal (L), a right audio terminal (R), a microphone terminal (M), and a ground terminal (GND).

Relay 79 includes switch 56, a processor 59, microphone 48, an ADC 61, and a ground power supply 57.

Left ear pad 554 includes electromagnetic speaker 47a. Right ear pad 55 includes electromagnetic speaker 47b and pulse sensor 153. Pulse sensor 153 includes a PD 159 which can receive infrared rays and an LED 152 which can output infrared rays.

Earphone 94 can be attached to an ear of a user such that LED 202 and PD 201 face the skin of the external ear.

In accordance with various embodiments, processor 59 may be implemented as a single integrated circuit (IC) or as multiple communicatively coupled IC's and/or discrete circuits. Processor 59 can be implemented in accordance with various known technologies.

In one embodiment, processor 59 includes one or more circuits or units configurable to perform one or more data computing procedures or processes. For example, processor 59 may include controllers, microprocessors, microcontrollers, application specific integrated circuits (ASICs), digital signal processors, programmable logic devices, field programmable gate arrays, or any combination of these devices or structures, or other known devices and structures, to perform the functions described below.

Processor 59 can control turn-on of LED 152 and receive a signal from PD 159, and when reception waves received by PD 159 periodically vary, it can calculate pulses based on the period.

Processor 59, PD 159, and LED 152 can operate by receiving a power supply voltage through signal line V connected to the power supply terminal (V) of earphone plug 54.

ADC 61 can convert an analog signal output from PD 159 into a digital signal and output the digital signal to processor 59.

Microphone 48 can supply an input audio signal to processor 59 and switch 56.

Switch 56 can select a control signal from processor 59 or an audio signal from microphone 48 and supply the selected signal to earphone plug 54 through signal line M connected to the microphone terminal (M).

Ground power supply 57 can transmit or receive a ground voltage to or from earphone plug 54 through signal line G connected to the ground terminal (GND).

Electromagnetic speaker 47a can receive a left audio signal to left ear pad 554 through signal line L connected to the left audio terminal (L) and output the left audio signal. Electromagnetic speaker 47b can receive a right audio signal to right ear pad 55 through signal line R connected to the right audio terminal (R) and output the right audio signal.

(Connection Relation Among Constituent Elements in Earphone)

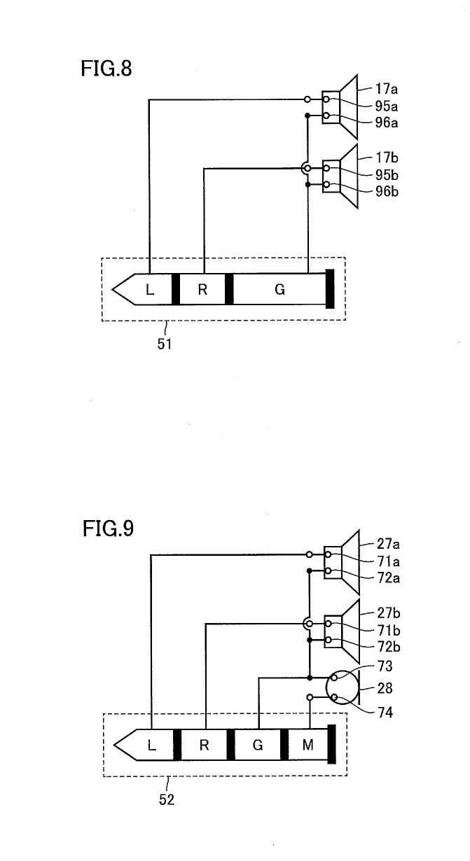

FIG. 8 is a diagram showing connection of constituent elements in three-electrode plug earphone 91.

Three-electrode plug 51 of three-electrode plug earphone 91 is a plug in conformity with Electronic Industries Association of Japan (EIAJ) standards. Three-electrode plug 51 has a diameter of 3.5 mm. Three-electrode plug 51 includes a left audio terminal (L) (a first terminal), a right audio terminal (R) (a second terminal), and a ground terminal (GND) (a third terminal) sequentially from a tip end. A portion shown with black in FIG. 8 is formed of an insulator.

Electromagnetic speaker 17a includes an input terminal 95a and a ground voltage input terminal (a ground terminal) 96a. Electromagnetic speaker 17b includes an input terminal 95b and a ground voltage input terminal (a ground terminal) 96b.

The left audio terminal (L) can be connected to input terminal 95a of electromagnetic speaker 17a. The right audio terminal (R) can be connected to input terminal 95b of electromagnetic speaker 17b. The ground terminal (GND) can be connected to ground terminal 96a of electromagnetic speaker 17a and ground terminal 96b of electromagnetic speaker 17b.

FIG. 9 is a diagram showing connection of constituent elements in four-electrode plug earphone 92.

Four-electrode plug 52 of four-electrode plug earphone 92 is a plug in conformity with the EIAJ standards. Four-electrode plug 52 has a diameter of 3.5 mm. A signal sequence of four-electrode plug 52 is in conformity with Cellular Telephone Industry Association (CTIA). Four-electrode plug 52 includes a left audio terminal (L) (a first terminal), a right audio terminal (R) (a second terminal), a ground terminal (GND) (a third terminal), and a microphone terminal (M) (a fourth terminal) sequentially from a tip end.

Electromagnetic speaker 27a includes an input terminal 71a and a ground voltage input terminal (a ground terminal) 72a. Electromagnetic speaker 27b includes an input terminal 71b and a ground voltage input terminal (a ground terminal) 72b. Microphone 28 includes an output terminal 74 and a ground voltage input terminal (a ground terminal) 73.

The left audio terminal (L) can be connected to input terminal 71a of electromagnetic speaker 27a. The right audio terminal (R) can be connected to input terminal 71b of electromagnetic speaker 27b. The ground terminal (GND) can be connected to ground terminal 72a of electromagnetic speaker 27a, ground terminal 72b of electromagnetic speaker 27b, and ground terminal 73 of microphone 28. The microphone terminal (M) can be connected to output terminal 74 of microphone 28.

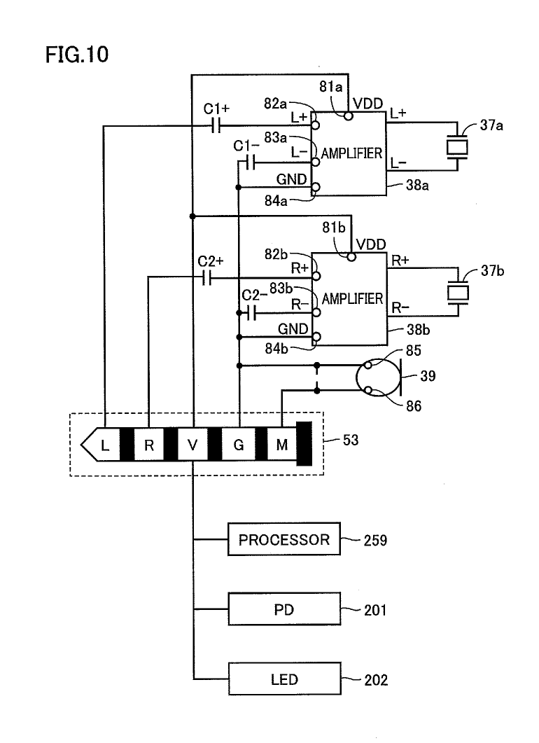

FIG. 10 is a diagram showing connection of constituent elements in five-electrode plug earphone 93 (piezoelectric).

Five-electrode plug 53 of five-electrode plug earphone 93 (piezoelectric) includes a left audio terminal (L) (a first terminal), a right audio terminal (R) (a second terminal), a power supply terminal (V) (a third terminal), a ground terminal (GND) (a fourth terminal), and a microphone terminal (M) (a fifth terminal) sequentially from a tip end.

Differential amplifier 38a includes a positive-side input terminal 82a, a negative-side input terminal 83a, a power supply voltage input terminal (a power supply terminal) 81a, and a ground voltage input terminal (a ground terminal) 84a. Differential amplifier 38b includes a positive-side input terminal 82b, a negative-side input terminal 83b, a power supply voltage input terminal (a power supply terminal) 81b, and a ground voltage input terminal (a ground terminal) 84b. Microphone 39 includes an output terminal 86 and a ground voltage input terminal (a ground terminal) 85.

The left audio terminal (L) can be connected to positive-side input terminal 82a of differential amplifier 38a with a capacitor C1+(=0.1 μF) being interposed. The right audio terminal (R) can be connected to positive-side input terminal 82b of differential amplifier 38b with a capacitor C2+(=0.1 μF) being interposed. The power supply terminal (V) can be connected to power supply terminal 81a of differential amplifier 38a, power supply terminal 81b of differential amplifier 38b, processor 259, PD 201, and LED 202. The ground terminal (GND) can be connected to negative-side input terminal 83a of differential amplifier 38a with a capacitor C1−(=0.1 μF) being interposed. The ground terminal (GND) can further be connected to ground terminal 84a of differential amplifier 38a. The ground terminal (GND) can be connected to negative-side input terminal 83b of differential amplifier 38b with capacitor C2−(=0.1 μF) being interposed. The ground terminal (GND) can further be connected to ground terminal 84b of differential amplifier 38b. The ground terminal (GND) can further be connected to ground terminal 85 of microphone 39. The microphone terminal (M) can be connected to output terminal 86 of microphone 39.

Differential amplifier 38a can amplify a difference between a voltage of positive-side input terminal 82a and a voltage of negative-side input terminal 83a and supply a voltage (L+, L−) to piezoelectric element 37a. Piezoelectric element 37a oscillates in accordance with magnitude of the supplied voltage. Differential amplifier 38b can amplify a difference between a voltage of positive-side input terminal 82b and a voltage of negative-side input terminal 83b and supply a voltage (R+, R−) to piezoelectric element 37b. Piezoelectric element 37b can oscillate in accordance with magnitude of the supplied voltage. To differential amplifiers 38a and 38b, 5 to 30 Vpp (that is, a difference in potential between a maximum value and a minimum value of an alternating-current voltage waveform being from 5 to 30 V) is applied, and therefore an efficient class D or class H amplifier is used.

The reason why differential amplifiers 38a and 38b are necessary is that piezoelectric elements 37a and 37b are driven by an input signal at a high voltage. If differential amplifiers 38a and 38b are located on a side of portable terminal 1, in order to supply a voltage output from differential amplifiers 38a and 38b to piezoelectric elements 37a and 37b, a plug requires four terminals for outputting voltages (L+, L−, R+, R−). Consequently, the plug is a six-electrode plug with the ground terminal (GND) and the microphone terminal (M) being added, and an earphone jack which can adapt to the six-electrode plug is required also on the side of the portable terminal.

A configuration allowing connection of all of the three-electrode plug, the four-electrode plug, and the six-electrode plug with an earphone jack which can adapt to the six-electrode plug is complicated or difficult. Therefore, in an embodiment, an earphone including a five-electrode plug is employed and differential amplifiers 38a and 38b are located on a side of the earphone.

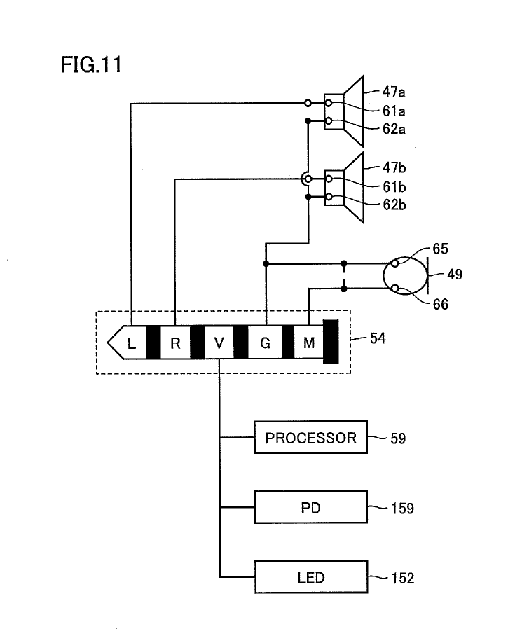

FIG. 11 is a diagram showing connection of constituent elements in five-electrode plug earphone 94 (electromagnetic).

Five-electrode plug 54 of five-electrode plug earphone 94 (electromagnetic) includes a left audio terminal (L) (a first terminal), a right audio terminal (R) (a second terminal), a power supply terminal (V) (a third terminal), a ground terminal (GND) (a fourth terminal), and a microphone terminal (M) (a fifth terminal) sequentially from a tip end.

Electromagnetic speaker 47a includes an input terminal 61a and a ground voltage input terminal (a ground terminal) 62a. Electromagnetic speaker 47b includes an input terminal 61b and a ground voltage input terminal (a ground terminal) 62b. Microphone 49 includes an output terminal 66 and a ground voltage input terminal (a ground terminal) 65.

The left audio terminal (L) can be connected to input terminal 61a of electromagnetic speaker 47a. The right audio terminal (R) can be connected to input terminal 61b of electromagnetic speaker 47b. The power supply terminal (V) can be connected to processor 59, PD 159, and LED 152. The ground terminal (GND) can be connected to ground terminal 62a of electromagnetic speaker 47a, ground terminal 62b of electromagnetic speaker 47b, and ground terminal 65 of microphone 49. The microphone terminal (M) can be connected to output terminal 66 of microphone 49.

(Positional Relation Between Terminals of Earphone Jack and Terminals in Three-Electrode Plug, Four-Electrode Plug, and Five-Electrode Plug)

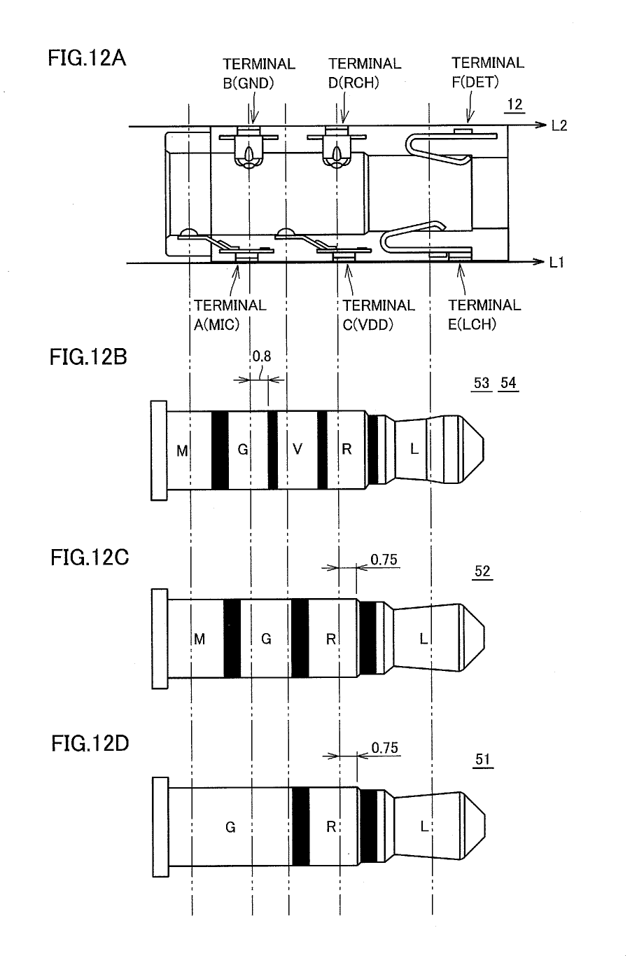

FIG. 12A is a diagram showing earphone jack 12.

Earphone jack 12 includes a terminal A (MIC) (a first terminal), a terminal B (GND) (a second terminal), a terminal C (VDD) (a third terminal), a terminal D (Rch) (a fourth terminal), a terminal E (Lch) (a fifth terminal), and a terminal F (DET) (a sixth terminal) in the order of proximity to an insertion port.

The terminal A (MIC) (the first terminal), the terminal C (VDD) (the third terminal), and the terminal E (Lch) (the fifth terminal) can be arranged along a first line L1 in parallel to a direction of insertion over a cylindrical inner wall of earphone jack 12.

The terminal B (GND) (the second terminal), the terminal D (Rch) (the fourth terminal), and the terminal F (DET) (the sixth terminal) can be arranged along a second line L2 in parallel to the direction of insertion over the cylindrical inner wall of earphone jack 12 and opposed to first line L1.

FIG. 12B is a diagram showing five-electrode plug 53, 54.

Five-electrode plug 53, 54 of five-electrode plug earphone 93, 94 can be connected to earphone jack 12 as below when it is completely inserted into earphone jack 12.

The left audio terminal (L) is connected to the terminal E (Lch) and the terminal F (DET). The right audio terminal (R) is connected to the terminal D (Rch). The power supply terminal (V) is connected to the terminal C (VDD). The ground terminal (G) can be connected to the terminal B (GND). The microphone terminal (M) can be connected to the terminal A (MIC).

FIG. 12C is a diagram showing four-electrode plug 52.

Four-electrode plug 52 of four-electrode plug earphone 92 can be connected to earphone jack 12 as below when it is completely inserted into earphone jack 12.

The left audio terminal (L) is connected to the terminal E (Lch) and the terminal F (DET). The right audio terminal (R) is connected to the terminal D (Rch). The ground terminal (G) is connected to the terminal B (GND) and the terminal C (VDD). The microphone terminal (M) can be connected to the terminal A (MIC).

FIG. 12D is a diagram showing three-electrode plug 51.

Three-electrode plug 51 of three-electrode plug earphone 91 can be connected to earphone jack 12 as below when it is completely inserted into earphone jack 12.

The left audio terminal (L) is connected to the terminal E (Lch) and the terminal F (DET). The right audio terminal (R) is connected to the terminal D (Rch). The ground terminal (G) can be connected to the terminal A (MIC), the terminal B (GND), and the terminal C (VDD).

(Configuration for Transmission and Reception of Signal to and from Earphone)

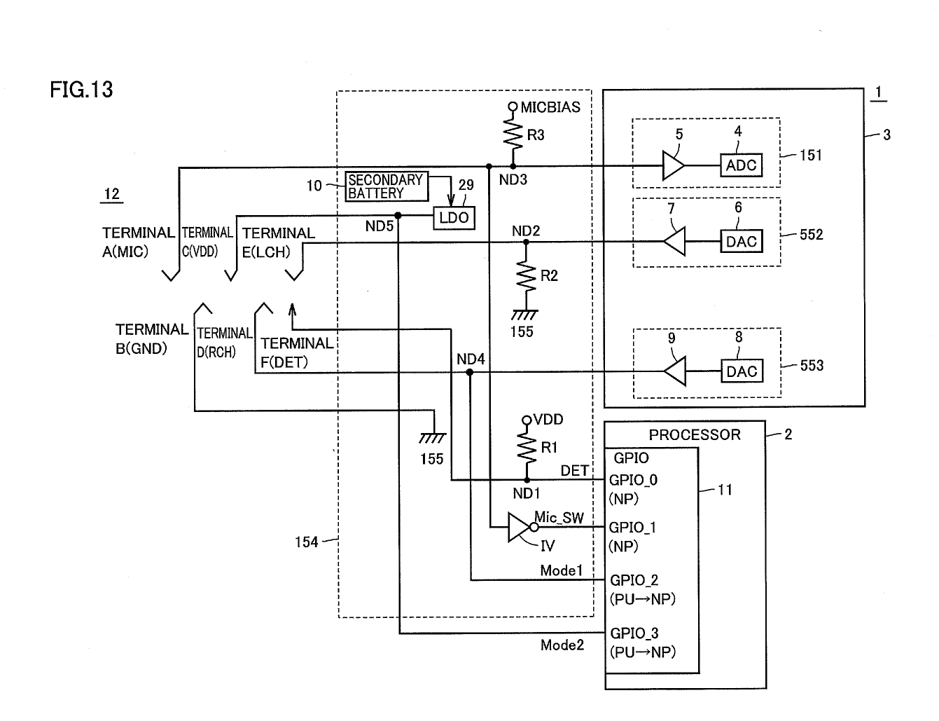

FIG. 13 is a diagram showing a configuration associated with transmission and reception of a signal to and from an earphone in portable terminal 1.

Audio processing unit 3 includes a microphone audio processing unit 151, an audio output unit 552, and an audio output unit 553.

Microphone audio processing unit 151 includes an amplifier 5 and an AD converter 4. Amplifier 5 is connected to the terminal A (MIC) of earphone jack 12. Amplifier 5 can amplify an audio signal output from the terminal A (MIC). AD converter 4 can convert an audio signal output from amplifier 5 into a digital signal.

Audio output unit 552 includes a DA converter 6 and an amplifier 7. DA converter 6 can convert a digital audio signal for the left ear into an analog audio signal. Amplifier 7 can amplify or attenuate an audio signal output from DA converter 6. Amplifier 7 can be connected to the terminal E (Lch) of earphone jack 12.

Audio output unit 553 includes a DA converter 8 and an amplifier 9. DA converter 8 can convert a digital audio signal for the right ear into an analog audio signal. Amplifier 9 can amplify or attenuate an audio signal output from DA converter 8. Amplifier 9 can be connected to the terminal D (Rch) of earphone jack 12.

Voltage setting unit 154 includes secondary battery 10, LDO 29, a pull-up resistor R1, a pull-down resistor R2, a pull-up resistor R3, an inverter IV, and a ground 155.

Pull-up resistor R1 can be connected between a node ND1 on a line between the terminal F (DET) of earphone jack 12 and processor 2 and a power supply voltage VDD for pull-up.

Pull-down resistor R2 can be connected between a node ND2 on a line between the terminal E (Lch) of earphone jack 12 and audio output unit 552 and ground 155.

Pull-up resistor R3 can be connected between a node ND3 on a line between the terminal A (MIC) of earphone jack 12 and microphone audio processing unit 151 and a bias voltage MICBIAS for pull-up.

Inverter IV can invert a voltage of node ND3.

Ground 155 can be connected to the terminal B (GND) of earphone jack 12.

LDO 29 connected to secondary battery 10 can be connected to the terminal C (VDD) of earphone jack 12.

Processor 2 includes a general purpose input/output (GPIO) interface 11. GPIO interface 11 includes terminals GPIO_0, GPIO_1, GPIO_2, and GPIO_3. GPIO interface 11 can set voltages of terminals GPIO_0, GPIO_2, and GPIO_3 and can receive signals and voltages of terminals GPIO_0, GPIO_1, GPIO_2, and GPIO_3.

At the time of input, in the terminal, pull-up (PU) at several hundred kΩ to the power supply, pull-down (PD) at several hundred Ω to the ground, or neither of pull-up and pull-down (NP) can be set.

Terminal GPIO_0 can be connected to node ND1. Processor 2 can control pull-up of an output from terminal GPIO_0. Processor 2 can receive a detection signal DET input to terminal GPIO_0.

Terminal GPIO_1 can be connected to an output of inverter IV. Processor 2 can control pull-up of an output from terminal GPIO_1. Processor 2 can receive a signal Mic_SW input to terminal GPIO_1.

Terminal GPIO_2 can be connected to a node ND4 on a line between the terminal D (Rch) of earphone jack 12 and audio output unit 552. Processor 2 can control pull-up of an output from terminal GPIO_2. Processor 2 can receive a mode signal Mode1 input to terminal GPIO_2.

Terminal GPIO_3 can be connected to a node ND5 on a line between the terminal E (Lch) of earphone jack 12 and LDO 29. Processor 2 can control pull-up of an output from terminal GPIO_3. Processor 2 can receive a mode signal Mode2 input to terminal GPIO_3.

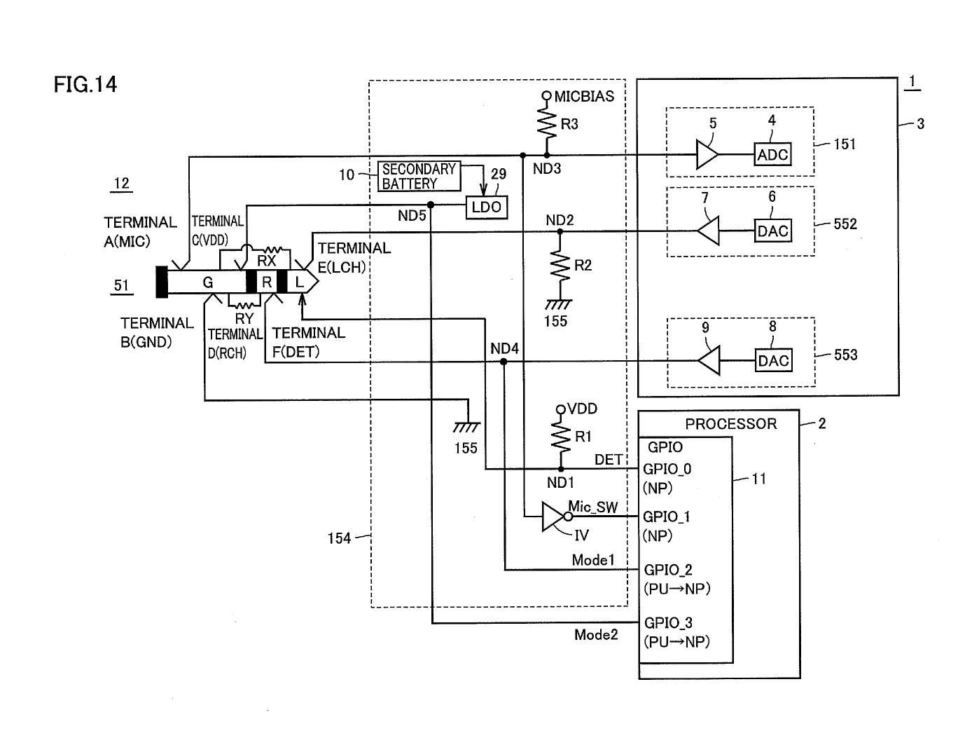

FIG. 14 is a diagram showing connection between three-electrode plug earphone 91 and constituent elements in portable terminal 1 when three-electrode plug 51 is inserted into earphone jack 12.

Electromagnetic speaker 17a connected between the left audio terminal (L) and the ground terminal (G) of three-electrode plug 51 is expressed as a resistor RX (=8Ω) when expressed as an equalization circuit. Electromagnetic speaker 17b connected between the right audio terminal (R) and the ground terminal (G) of three-electrode plug 51 is expressed as a resistor RY (=8Ω) when expressed as an equalization circuit.

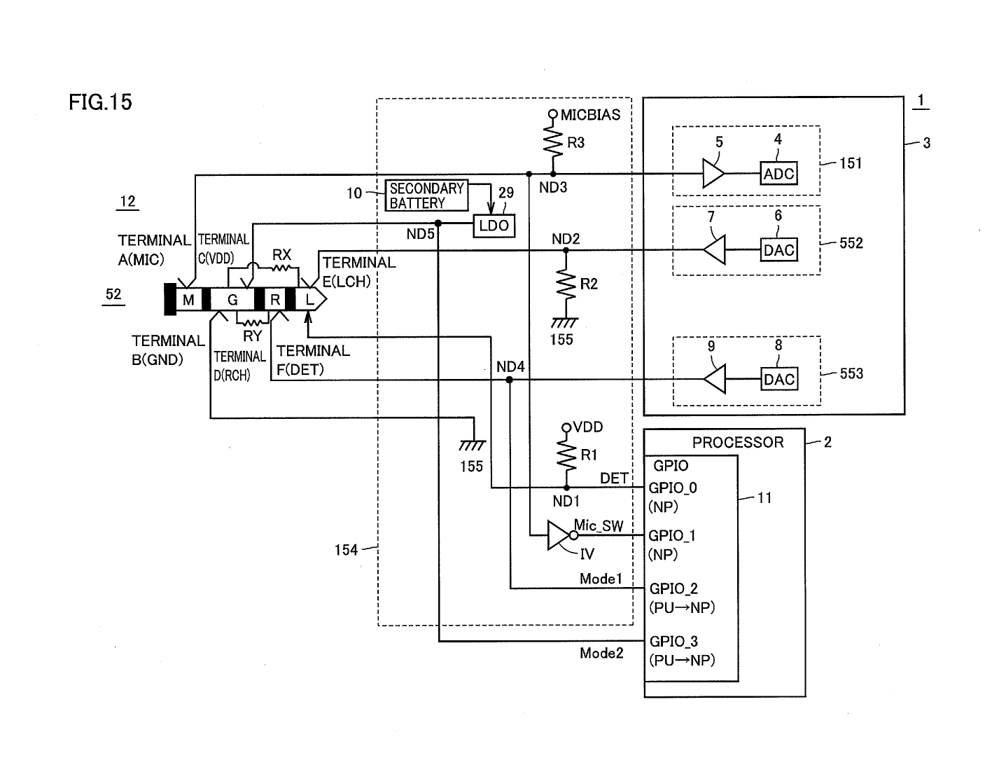

FIG. 15 is a diagram showing connection between four-electrode plug earphone 92 and constituent elements in portable terminal 1 when four-electrode plug 52 is inserted into earphone jack 12.

Electromagnetic speaker 27a connected between the left audio terminal (L) and the ground terminal (G) of four-electrode plug 52 is expressed as resistor RX (=8Ω) when expressed as an equalization circuit. Electromagnetic speaker 27b connected between the right audio terminal (R) and the ground terminal (G) of four-electrode plug 52 is expressed as resistor RY (=8Ω) when expressed as an equalization circuit.

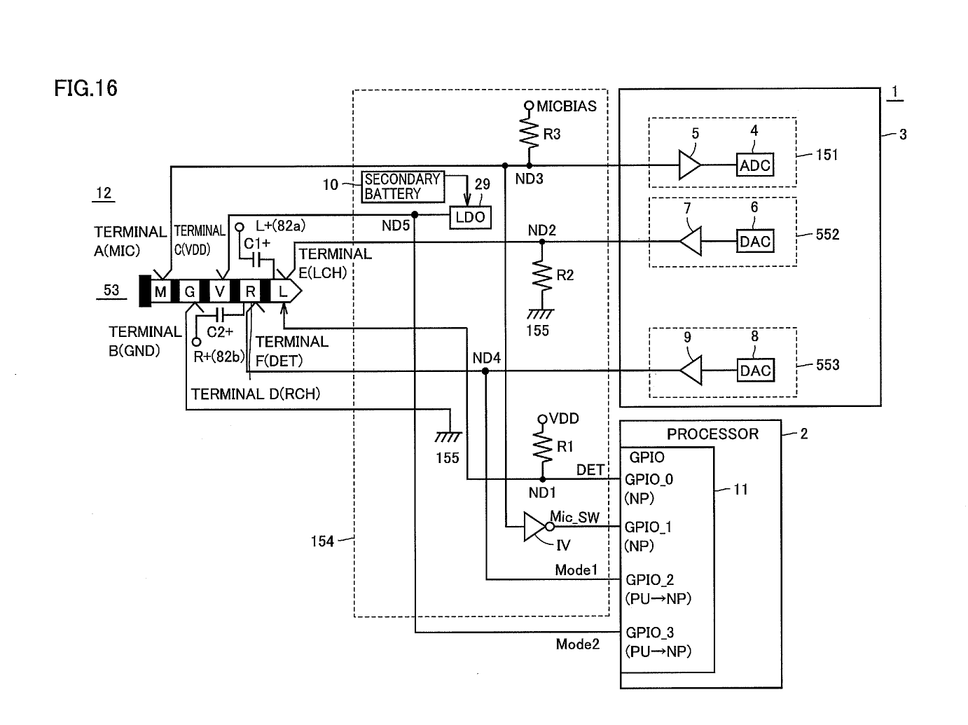

FIG. 16 is a diagram showing connection between five-electrode plug earphone 93 (piezoelectric) and constituent elements in portable terminal 1 when five-electrode plug 53 is inserted into earphone jack 12.

The left audio terminal (L) of five-electrode plug 53 can be connected to positive-side input terminal 82a of differential amplifier 38a with capacitor C1+ being interposed. The right audio terminal (R) of five-electrode plug 53 can be connected to positive-side input terminal 82b of differential amplifier 38b with capacitor C2+ being interposed. Therefore, the left audio terminal (L) and the right audio terminal (R) of five-electrode plug 53 are isolated in a direct-current state.

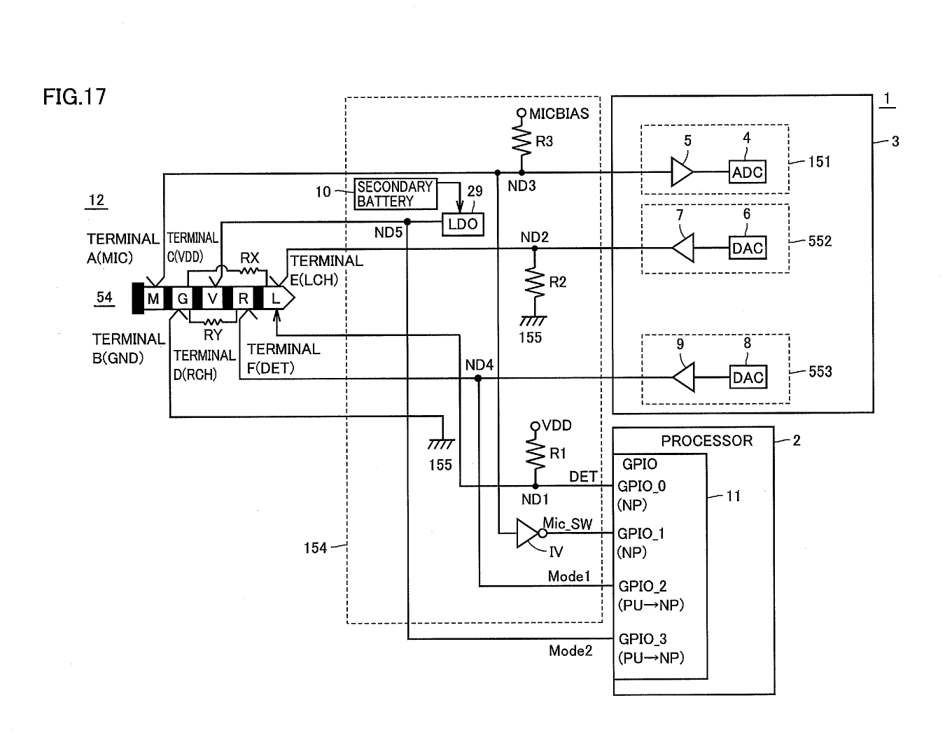

FIG. 17 is a diagram showing connection between five-electrode plug earphone 94 (electromagnetic) and constituent elements in portable terminal 1 when five-electrode plug 54 is inserted into earphone jack 12.

Electromagnetic speaker 47a connected between the left audio terminal (L) and the ground terminal (G) of five-electrode plug 54 is expressed as resistor RX (=8Ω) when expressed as an equalization circuit. Electromagnetic speaker 47b connected between the right audio terminal (R) and the ground terminal (G) of five-electrode plug 54 is expressed as resistor RY (=8Ω) when expressed as an equalization circuit.

(Determination of Insertion and Removal of Plug and Identification of Type of Plug)

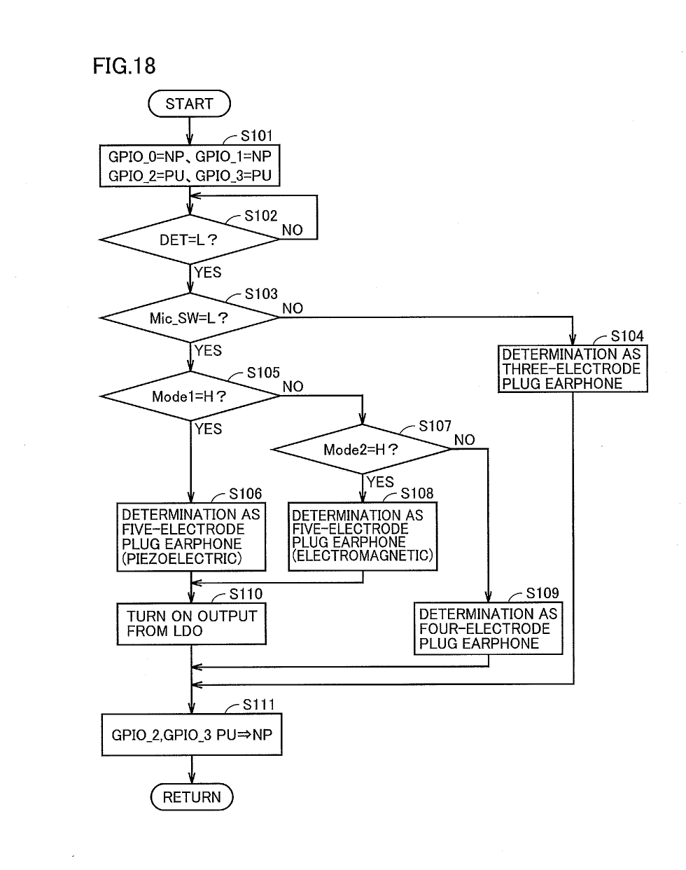

FIG. 18 is a flowchart showing a procedure for determining insertion and removal of a plug and for identifying a type of a plug.

Referring to FIGS. 13 to 18, in step S101, processor 2 can pull up GPIO_2 and GPIO_3 (PU) without pulling up GPIO_0 and GPIO_1 of GPIO interface 11 (NP).

As shown in FIG. 13, when a plug is not inserted in earphone jack 12, a voltage of detection node ND1 is pulled up by resistor R1 (=100 kΩ) connected to power supply voltage VDD and attains to the high level (H). Consequently, detection signal DET input to GPIO_0 attains to the high level (H).

As shown in FIGS. 14, 15, and 17, when plug 51, 52, or 54 is inserted in earphone jack 12, node ND1 can be connected to pull-up resistor R1 (=100 kΩ) connected to power supply voltage VDD, pull-down resistor R2 (=10 kΩ) connected to the ground, and resistor RX (=8Ω) connected to the ground terminal (G). Consequently, a voltage of node ND1 attains to the low level (L) and detection signal DET input to GPIO_0 attains to the low level (L).

As shown in FIG. 16, when plug 53 is inserted in earphone jack 12, node ND1 can be connected to pull-up resistor R1 (=100 kΩ) connected to power supply voltage VDD, pull-down resistor R2 (=10 kΩ) connected to the ground through the left audio terminal (L), and capacitor C1+(=0.1 μF) which is in a direct-current floating state through the left audio terminal (L). Consequently, a voltage of node ND1 attains to the low level (L) and detection signal DET input to GPIO_0 attains to the low level (L).

In step S102, processor 2 determines that the plug has been inserted in earphone jack 12 when detection signal DET is at the low level (L), and the process proceeds to step S103.

As shown in FIG. 14, node ND3 is connected to pull-up resistor R3 (=2.2 kΩ) connected to bias voltage MICBIAS. When three-electrode plug 51 is connected to earphone jack 12, node ND3 is further connected to the ground terminal (G) and hence it attains to the low level (L). Consequently, output from inverter IV connected to node ND3 attains to the high level (H) and signal Mic_SW input to GPIO_1 attains to the high level (H).

As shown in FIGS. 15, 16, and 17, when four-electrode plug 52 or five-electrode plug 53, 54 is connected to earphone jack 12, node ND3 is connected to the microphone terminal (M). Since the microphone terminal (M) serves as a condenser, node ND3 attains to the high level (H). Consequently, output from inverter IV connected to node ND3 attains to the low level (L) and signal Mic_SW input to GPIO_1 attains to the low level (L).

In step S103, processor 2 allows the process to proceed to step S104 when signal Mic_SW is at the high level (H) (that is, node ND3 is at the low level (L)) and allows the process to proceed to step S105 when signal Mic_SW is at the low level (L).

In step S104, processor 2 can determine that the inserted plug is three-electrode plug 51.

As GPIO_2 is pulled up in step S101, node ND4 can be pulled up. When four-electrode plug 52 or five-electrode plug 54 (electromagnetic) is connected to earphone jack 12 as shown in FIGS. 15 and 17, node ND4 can further be connected to resistor RY (=8Ω) connected to the ground. Consequently, node ND4 attains to the low level and mode signal Mode1 input to GPIO_2 attains to the low level.

As shown in FIG. 16, when five-electrode plug 53 (piezoelectric) is connected to earphone jack 12, node ND4 can further be connected to capacitor C2+(=0.1 μF) isolated when a direct current flows through the right audio terminal (R). Consequently, node ND4 maintains the high level and mode signal Mode1 input to GPIO_2 attains to the high level.

In step S105, processor 2 allows the process to proceed to step S107 when mode signal Mode1 is at the low level (L) and allows the process to proceed to step S106 when mode signal Mode1 is at the high level (H).

In step S106, processor 2 can determine that the inserted plug is five-electrode plug 53 (piezoelectric).

As GPIO_3 is pulled up in step S101, node ND5 can be pulled up. When four-electrode plug 52 is connected to earphone jack 12 as shown in FIG. 15, node ND5 can further be connected to the ground terminal (G). Consequently, node ND5 attains to the low level and mode signal Mode2 input to GPIO_3 attains to the low level.

As shown in FIG. 17, when five-electrode plug 54 (electromagnetic) is connected to earphone jack 12, node ND5 can further be connected to the power supply terminal (V). In the current state, no voltage is supplied to the power supply terminal (V) through LDO 29. Consequently, node ND5 maintains the high level and mode signal Mode2 input to GPIO_3 attains to the high level.

In step S107, processor 2 allows the process to proceed to step S109 when mode signal Mode2 is at the low level (L) and allows the process to proceed to step S108 when mode signal Mode2 is at the high level (H).

In step S108, processor 2 can determine that the inserted plug is five-electrode plug 54 (electromagnetic).

In step S109, processor 2 can determine that the inserted plug is four-electrode plug 52.

In step S110, processor 2 can start supply of power supply voltage VDD from secondary battery 10 through LDO 29 to earphone jack 12 by turning on an output from LDO 29.

In step S111, processor 2 can cancel pull-up of GPIO_2 and GPIO_3 (NP). When pull-up of GPIO_2 is canceled, the terminal D (RCH) can be used for transmission of a right audio signal. When pull-up of GPIO_3 is canceled, an unnecessary leakage current can be reduced.

(Process of Insertion of Plug into Earphone Jack)

Connection between terminals in a process of insertion of five-electrode plug 53 into earphone jack 12 will now be described. This is also applicable to a process of insertion of five-electrode plug 54 into earphone jack 12.

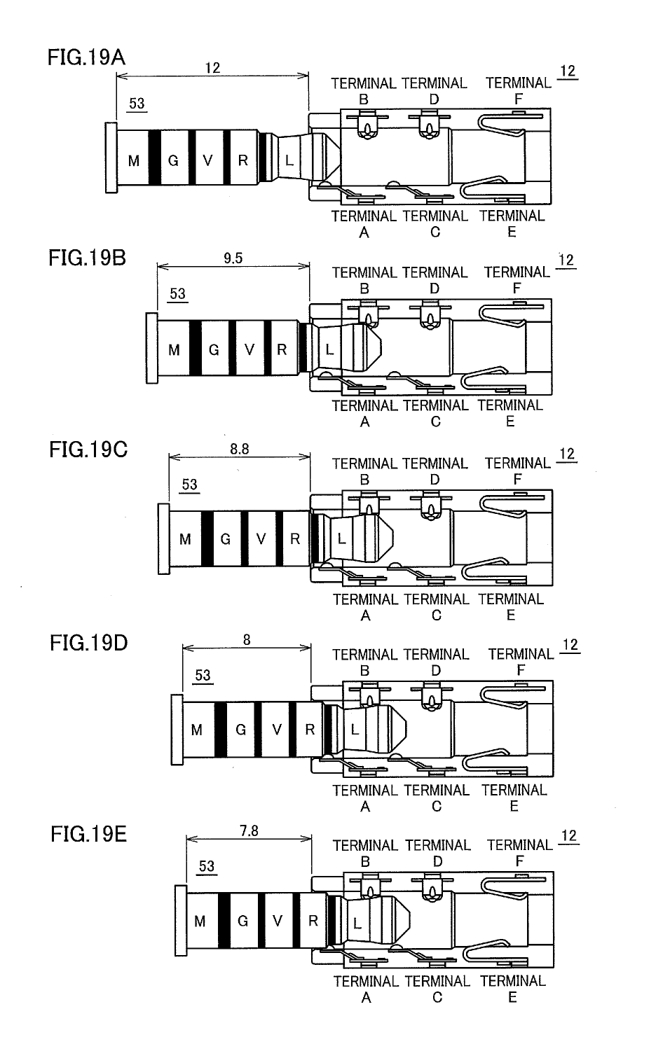

FIGS. 19A to 19E are diagrams showing a Stage 1 to a Stage 5 in a process of insertion of five-electrode plug 53 into earphone jack 12, respectively.

As shown in FIG. 19A, in Stage 1, the left audio terminal (L) of five-electrode plug 53 is connected to the terminal A (MIC) of earphone jack 12.

As shown in FIG. 19B, in Stage 2, the left audio terminal (L) of five-electrode plug 53 is connected to the terminal B (GND) of earphone jack 12.

As shown in FIG. 19C, in Stage 3, the left audio terminal (L) of five-electrode plug 53 is connected to the terminal A (MIC) and the terminal B (GND) of earphone jack 12.

As shown in FIG. 19D, in Stage 4, the left audio terminal (L) of five-electrode plug 53 is connected to the terminal B (GND) of earphone jack 12 and the right audio terminal (R) of five-electrode plug 53 is connected to the terminal A (MIC) of earphone jack 12.

As shown in FIG. 19E, in Stage 5, the left audio terminal (L) of five-electrode plug 53 is connected to the terminal B (GND) and the terminal C (VDD) of earphone jack 12, and the right audio terminal (R) of five-electrode plug 53 is connected to the terminal A (MIC) of earphone jack 12.

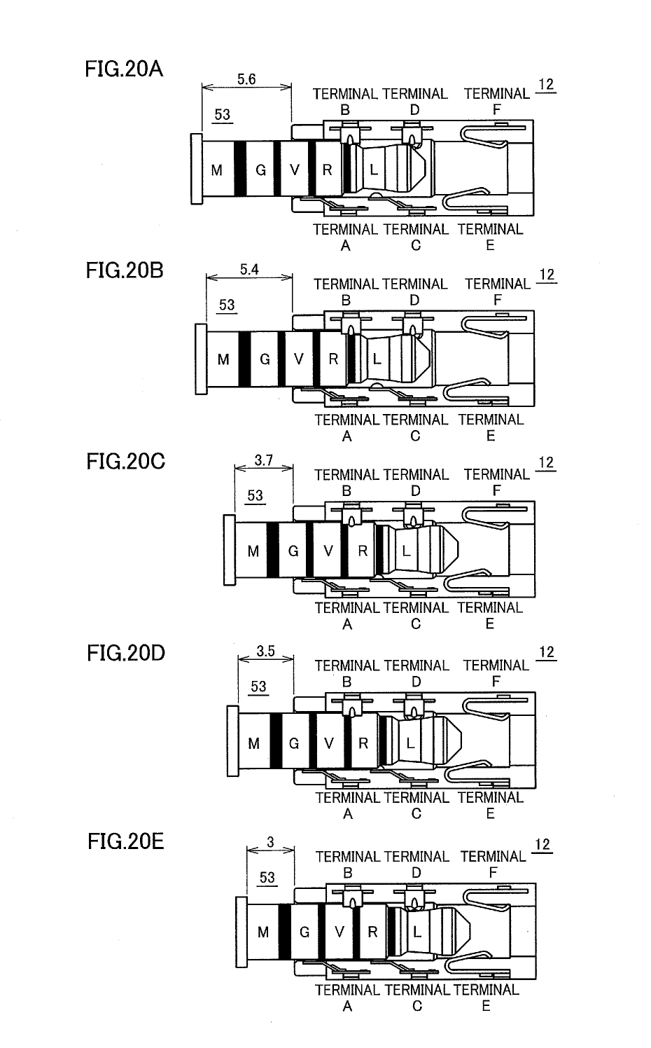

FIGS. 20A to 20E are diagrams showing a Stage 6 to a Stage 10 in the process of insertion of five-electrode plug 53 into earphone jack 12, respectively.

As shown in FIG. 20A, in Stage 6, the left audio terminal (L) of five-electrode plug 53 is connected to the terminal B (GND) of earphone jack 12 and the power supply terminal (V) of five-electrode plug 53 is connected to the terminal A (MIC) of earphone jack 12.

As shown in FIG. 20B, in Stage 7, the left audio terminal (L) of five-electrode plug 53 is connected to the terminal D (Rch) of earphone jack 12, the right audio terminal (R) of five-electrode plug 53 is connected to the terminal B (GND) of earphone jack 12, and the power supply terminal (V) of five-electrode plug 53 is connected to the terminal A (MIC) of earphone jack 12.

As shown in FIG. 20C, in Stage 8, the left audio terminal (L) of five-electrode plug 53 is connected to the terminal D (Rch) of earphone jack 12 and the right audio terminal (R) of five-electrode plug 53 is connected to the terminal B (GND) and the terminal C (VDD) of earphone jack 12. The ground terminal (G) of five-electrode plug 53 is connected to the terminal A (MIC) of earphone jack 12.

As shown in FIG. 20D, in Stage 9, the left audio terminal (L) of five-electrode plug 53 is connected to the terminal D (Rch) of earphone jack 12, the right audio terminal (R) of five-electrode plug 53 is connected to the terminal B (GND) and the terminal C (VDD) of earphone jack 12, and the ground terminal (G) of five-electrode plug 53 is connected to the terminal A (MIC) of earphone jack 12.

As shown in FIG. 20E, in Stage 10, the left audio terminal (L) of five-electrode plug 53 is connected to the terminal D (Rch) of earphone jack 12, the right audio terminal (R) of five-electrode plug 53 is connected to the terminal C (VDD) of earphone jack 12, the power supply terminal (V) of five-electrode plug 53 is connected to the terminal B (GND) of earphone jack 12, and the ground terminal (G) of five-electrode plug 53 is connected to the terminal A (MIC) of earphone jack 12.

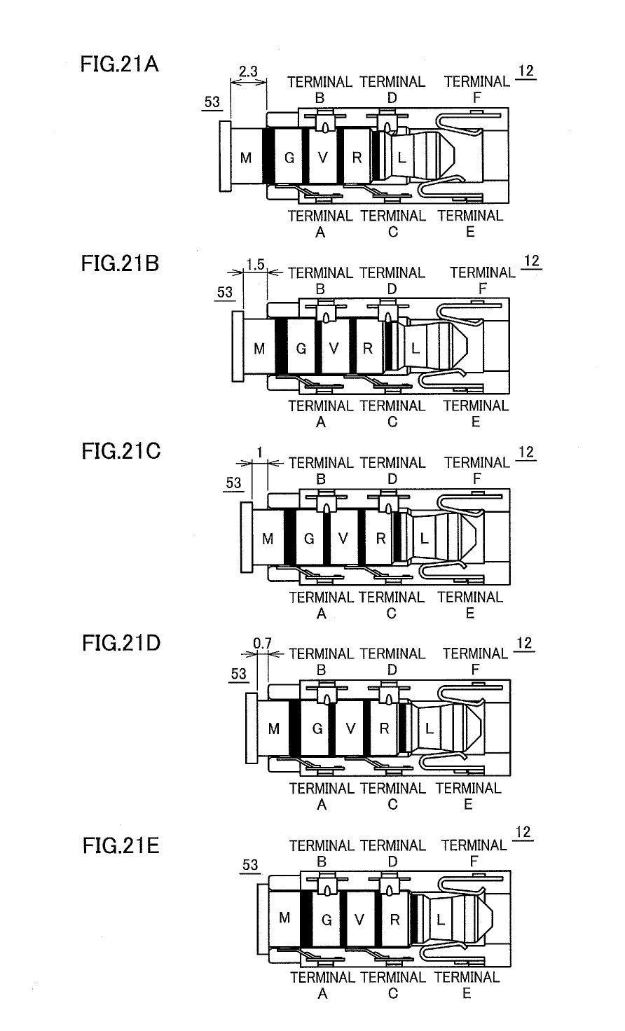

FIGS. 21A to 21E are diagrams showing a Stage 11 to a Stage 15 in the process of insertion of five-electrode plug 53 into earphone jack 12, respectively.

As shown in FIG. 21A, in Stage 11, the left audio terminal (L) of five-electrode plug 53 is connected to the terminal D (Rch) and the terminal E (Lch) of earphone jack 12, the right audio terminal (R) of five-electrode plug 53 is connected to the terminal C (VDD) of earphone jack 12, the power supply terminal (V) of five-electrode plug 53 is connected to the terminal B (GND) of earphone jack 12, and the ground terminal (G) of five-electrode plug 53 is connected to the terminal A (MIC) of earphone jack 12.

As shown in FIG. 21B, in Stage 12, the left audio terminal (L) of five-electrode plug 53 is connected to the terminal E (Lch) of earphone jack 12, the right audio terminal (R) of five-electrode plug 53 is connected to the terminal D (Rch) of earphone jack 12, the power supply terminal (V) of five-electrode plug 53 is connected to the terminal B (GND) and the terminal C (VDD) of earphone jack 12, and the ground terminal (G) of five-electrode plug 53 is connected to the terminal A (MIC) of earphone jack 12.

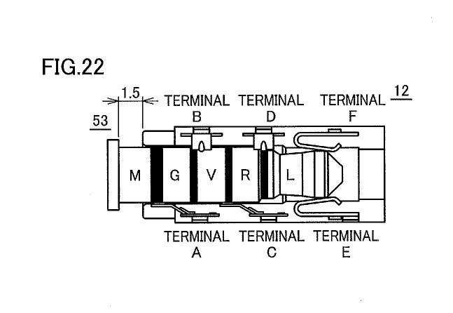

FIG. 22 is shown for the purpose of reference and it is a diagram showing Stage 12 in the process of insertion of five-electrode plug 53 into earphone jack 12 when a position of the terminal F (DET) of earphone jack 12 is displaced toward the insertion port.

As shown in FIG. 22, the left audio terminal (L) of five-electrode plug 53 is connected to the terminal E (Lch) and the terminal F (DET) of earphone jack 12, the right audio terminal (R) of five-electrode plug 53 is connected to the terminal D (Rch) of earphone jack 12, the power supply terminal (V) of five-electrode plug 53 is connected to the terminal B (GND) and the terminal C (VDD) of earphone jack 12, and the ground terminal (G) of five-electrode plug 53 is connected to the terminal A (MIC) of earphone jack 12.

As the left audio terminal (L) of five-electrode plug 53 is connected to the terminal E (Lch) and the terminal F (DET) of earphone jack 12, determination as YES is made in step S102 in the flowchart in FIG. 18 and determination as five-electrode plug 53 being inserted in earphone jack 12 is made. When determination as being inserted is made, determination processing in step S103 or later in the flowchart in FIG. 18 is performed. When identification as five-electrode plug 53 is made, power supply voltage VDD is supplied in step S110. In this state, however, the power supply terminal (V) of five-electrode plug 53 supplied with power supply voltage VDD is connected to the terminal B (GND) of earphone jack 12 and hence short-circuiting occurs.

In contrast, in FIG. 21B, the left audio terminal (L) of five-electrode plug 53 is not connected to the terminal F (DET) of earphone jack 12. Therefore, determination as NO is made in step S102 in the flowchart in FIG. 18 and determination as five-electrode plug 53 being inserted in earphone jack 12 is not made. Consequently, power supply voltage VDD is not supplied to the power supply terminal (V) of five-electrode plug 53 and short-circuiting is prevented from occurring.

Referring again to FIGS. 21A to 21E, as shown in FIG. 21C, in Stage 13, the left audio terminal (L) of five-electrode plug 53 can be connected to the terminal E (Lch) and the terminal F (DET) of earphone jack 12, the right audio terminal (R) of five-electrode plug 53 can be connected to the terminal D (Rch) of earphone jack 12, the power supply terminal (V) of five-electrode plug 53 can be connected to the terminal C (VDD) of earphone jack 12, and the microphone terminal (M) of five-electrode plug 53 can be connected to the terminal A (MIC) of earphone jack 12.

In this state, as the left audio terminal (L) of five-electrode plug 53 is connected to the terminal E (Lch) and the terminal F (DET) of earphone jack 12, determination as five-electrode plug 53 being inserted in earphone jack 12 can be made. When determination as being inserted is made and identification as five-electrode plug 53 is further made, power supply voltage VDD can be supplied. In this state, since the power supply terminal (V) of five-electrode plug 53 supplied with power supply voltage VDD is not connected to the terminal B (GND) of earphone jack 12, short-circuiting does not occur.

As shown in FIGS. 21D and 21E, in Stage 14 and Stage 15, the left audio terminal (L) of five-electrode plug 53 can be connected to the terminal E (Lch) and the terminal F (DET) of earphone jack 12, the right audio terminal (R) of five-electrode plug 53 can be connected to the terminal D (Rch) of earphone jack 12, the power supply terminal (V) of five-electrode plug 53 can be connected to the terminal C (VDD) of earphone jack 12, and the ground terminal (G) of five-electrode plug 53 can be connected to the terminal B (GND) of earphone jack 12.

As set forth above, according to the portable terminal and the five-electrode plug earphone in an embodiment, the earphone jack side of the portable terminal and the plug side of the five-electrode plug earphone (piezoelectric) and the five-electrode plug earphone (electromagnetic) include terminals for the power supply voltage, so that the power supply voltage can be supplied to the five-electrode plug earphone (piezoelectric) and the five-electrode plug earphone (electromagnetic).

With the terminals of the five-electrode plug being aligned sequentially in the order of the left audio terminal (L), the right audio terminal (R), the power supply terminal (V), the ground terminal (GND), and the microphone terminal (M) from the tip end, the portable terminal including an earphone jack for five electrodes can also be connected to the conventional three-electrode and four-electrode plug earphones.

In an embodiment, a difference in impedance between the speaker included in the three-electrode plug earphone, the four-electrode plug earphone, and five-electrode plug earphone and the differential amplifier included in the five-electrode plug earphone (piezoelectric) is made use of, so that whether an earphone inserted in the earphone jack is the five-electrode plug earphone (piezoelectric) or the three-electrode plug earphone, the four-electrode plug earphone, or the five-electrode plug earphone (electromagnetic speaker) can be identified.

In an embodiment, depending on whether a terminal of a plug to which a line through which electric power is supplied to the processor is connected is a ground terminal or a power supply terminal, whether an earphone inserted in an earphone jack is a four-electrode plug earphone or a five-electrode plug earphone (electromagnetic speaker) can be identified.

In an embodiment, after the inserted earphone has been identified as the five-electrode plug earphone (piezoelectric) or the five-electrode plug earphone (electromagnetic), the power supply voltage is supplied from the portable terminal to the five-electrode plug. When the power supply terminal (V) of the five-electrode plug is connected to the terminal B (GND) of the earphone jack, the left audio terminal (L) of the five-electrode plug is not connected to the terminal F (DET) of the earphone jack and hence short-circuiting can be prevented from occurring.

Though a portable terminal is described by way of example of an electronic device in an embodiment, the electronic device in the present disclosure is not limited to the portable terminal but devices such as personal computers or tablets are also encompassed.

In an embodiment, though resistor RX which is an equalization circuit of speaker 17a and resistor RY which is an equalization circuit of speaker 17b have a value of 8Ω, limitation thereto is not intended. Even when resistors RX and RY have a value of 16Ω or 32Ω, determination of insertion and removal of the plug and identification of a type of the plug described in an embodiment are applicable.

Though earphone jack 12 of a portable terminal in an embodiment can be connected to three-electrode plug earphone 91, four-electrode plug earphone 92, five-electrode plug earphone 93 (piezoelectric), and five-electrode plug earphone 94 (electromagnetic), limitation thereto is not intended. The earphone jack may be connected to only any one earphone or only any multiple earphones of four earphones.

A process of insertion of a five-electrode plug into earphone jack 12 described with reference to FIGS. 19A to 22 may also be applicable only to five-electrode plug 53, only to five-electrode plug 54, or both of five-electrode plug 53 and five-electrode plug 54.

It should be understood that an embodiment disclosed herein is illustrative and non-restrictive in every respect. The scope of the present disclosure is defined by the terms of the claims rather than the description above and is intended to include any modifications within the scope and meaning equivalent to the terms of the claims.

1. A five-electrode plug earphone comprising:
a first electromagnetic speaker configured to include an input terminal and a ground terminal;
a second electromagnetic speaker configured to include an input terminal and a ground terminal;
a microphone configured to include an output terminal and a ground terminal;
a first processor; and
a five-electrode plug configured to include a first terminal, a second terminal, a third terminal, a fourth terminal, and a fifth terminal sequentially from a tip end,
the first terminal of the five-electrode plug being configured to be connected to the input terminal of the first electromagnetic speaker,
the second terminal of the five-electrode plug being configured to be connected to the input terminal of the second electromagnetic speaker,
the third terminal of the five-electrode plug being configured to be connected to the first processor,
the fourth terminal of the five-electrode plug being configured to be connected to the ground terminal of the first electromagnetic speaker, the ground terminal of the second electromagnetic speaker, and the ground terminal of the microphone, and
the fifth terminal of the five-electrode plug being configured to be connected to the output terminal of the microphone.

2. A five-electrode plug earphone comprising:
a first differential amplifier configured to include a first input terminal, a second input terminal, a power supply terminal, and a ground terminal and to amplify a difference between a voltage of the first input terminal and a voltage of the second input terminal;
a second differential amplifier configured to include a first input terminal, a second input terminal, a power supply terminal, and a ground terminal and to amplify a difference between a voltage of the first input terminal and a voltage of the second input terminal;
a first piezoelectric element configured to receive a voltage amplified by the first differential amplifier;
a second piezoelectric element configured to receive a voltage amplified by the second differential amplifier;
a microphone including an output terminal and a ground terminal;
a first processor; and
a five-electrode plug configured to include a first terminal, a second terminal, a third terminal, a fourth terminal, and a fifth terminal sequentially from a tip end,
the first terminal of the five-electrode plug being configured to be connected to the first input terminal of the first differential amplifier,
the second terminal of the five-electrode plug being configured to be connected to the first input terminal of the second differential amplifier,
the third terminal of the five-electrode plug being configured to be connected to the power supply terminal of the first differential amplifier, the power supply terminal of the second differential amplifier, and the first processor,
the fourth terminal of the five-electrode plug being configured to be connected to the ground terminal of the first differential amplifier, the ground terminal of the second differential amplifier, the ground terminal of the microphone, the second input terminal of the first differential amplifier, and the second input terminal of the second differential amplifier, and
the fifth terminal of the five-electrode plug being configured to be connected to the output terminal of the microphone.

3. The five-electrode plug earphone according to claim 1, the five-electrode plug earphone further comprising a pulse sensor, wherein
the first processor is configured to control the pulse sensor and to receive a signal from the pulse sensor, and
the third terminal of the five-electrode plug is configured to be connected further to the pulse sensor.

4. An electronic device comprising:
an earphone jack which can be connected to a five-electrode plug earphone of a first type,
the five-electrode plug earphone of the first type including
a first electromagnetic speaker including an input terminal and a ground terminal,
a second electromagnetic speaker including an input terminal and a ground terminal,
a microphone including an output terminal and a ground terminal,
a first processor, and
a five-electrode plug including a first terminal, a second terminal, a third terminal, a fourth terminal, and a fifth terminal sequentially from a tip end,
the first terminal of the five-electrode plug being configured to be connected to the input terminal of the first electromagnetic speaker,
the second terminal of the five-electrode plug being configured to be connected to the input terminal of the second electromagnetic speaker,
the third terminal of the five-electrode plug being configured to be connected to the first processor,
the fourth terminal of the five-electrode plug being configured to be connected to the ground terminal of the first electromagnetic speaker, the ground terminal of the second electromagnetic speaker, and the ground terminal of the microphone, and
the fifth terminal of the five-electrode plug being configured to be connected to the output terminal of the microphone,
the earphone jack including a first terminal, a second terminal, a third terminal, a fourth terminal, a fifth terminal, and a sixth terminal in an order of proximity to an insertion port;
a microphone audio processing unit configured to be connected to the first terminal of the earphone jack;
a ground power supply configured to be connected to the second terminal of the earphone jack;
an electric power supply unit configured to be connected to the third terminal of the earphone jack;
a first audio output unit configured to be connected to the fourth terminal of the earphone jack;
a second audio output unit configured to be connected to the fifth terminal of the earphone jack; and
a second processor configured to be connected to the sixth terminal of the earphone jack and configured to determine insertion of a plug into the earphone jack,
when the five-electrode plug earphone of the first type is completely inserted in the earphone jack,
the first terminal of the earphone jack being configured to be connected to the fifth terminal of the five-electrode plug,
the second terminal of the earphone jack being configured to be connected to the fourth terminal of the five-electrode plug,
the third terminal of the earphone jack being configured to be connected to the third terminal of the five-electrode plug,
the fourth terminal of the earphone jack being configured to be connected to the second terminal of the five-electrode plug,
the fifth terminal of the earphone jack being configured to be connected to the first terminal of the five-electrode plug, and
the sixth terminal of the earphone jack being configured to be connected to the first terminal of the five-electrode plug.

5. The electronic device according to claim 4, wherein
the earphone jack can be connected further to a five-electrode plug earphone of a second type,
the five-electrode plug earphone of the second type includes
a first differential amplifier configured to include a first input terminal, a second input terminal, a power supply terminal, and a ground terminal and to amplify a difference between a voltage of the first input terminal and a voltage of the second input terminal,
a second differential amplifier configured to include a first input terminal, a second input terminal, a power supply terminal, and a ground terminal and to amplify a difference between a voltage of the first input terminal and a voltage of the second input terminal,
a first piezoelectric element configured to receive a voltage amplified by the first differential amplifier,
a second piezoelectric element configured to receive a voltage amplified by the second differential amplifier,
a microphone including an output terminal and a ground terminal,
a first processor, and
a five-electrode plug including a first terminal, a second terminal, a third terminal, a fourth terminal, and a fifth terminal sequentially from a tip end,
the first terminal of the five-electrode plug is configured to be connected to the first input terminal of the first differential amplifier,
the second terminal of the five-electrode plug is configured to be connected to the first input terminal of the second differential amplifier,
the third terminal of the five-electrode plug is configured to be connected to the power supply terminal of the first differential amplifier, the power supply terminal of the second differential amplifier, and the first processor,
the fourth terminal of the five-electrode plug is configured to be connected to the ground terminal of the first differential amplifier, the ground terminal of the second differential amplifier, the ground terminal of the microphone, the second input terminal of the first differential amplifier, and the second input terminal of the second differential amplifier, and
the fifth terminal of the five-electrode plug is configured to be connected to the output terminal of the microphone, and
when the five-electrode plug earphone of the second type is completely inserted in the earphone jack,
the first terminal of the earphone jack is configured to be connected to the fifth terminal of the five-electrode plug,
the second terminal of the earphone jack is configured to be connected to the fourth terminal of the five-electrode plug,
the third terminal of the earphone jack is configured to be connected to the third terminal of the five-electrode plug,
the fourth terminal of the earphone jack is configured to be connected to the second terminal of the five-electrode plug,
the fifth terminal of the earphone jack is configured to be connected to the first terminal of the five-electrode plug, and
the sixth terminal of the earphone jack is configured to be connected to the first terminal of the five-electrode plug.

6. The electronic device according to claim 4, wherein
the earphone jack can be connected further to a three-electrode plug earphone,
the three-electrode plug earphone includes
a first electromagnetic speaker including an input terminal and a ground terminal,
a second electromagnetic speaker including an input terminal and a ground terminal, and
a three-electrode plug including a first terminal, a second terminal, and a third terminal sequentially from a tip end,
the first terminal of the three-electrode plug is configured to be connected to the input terminal of the first electromagnetic speaker,
the second terminal of the three-electrode plug is configured to be connected to the input terminal of the second electromagnetic speaker,
the third terminal of the three-electrode plug is configured to be connected to the ground terminal of the first electromagnetic speaker and the ground terminal of the second electromagnetic speaker, and
when the three-electrode plug earphone is completely inserted in the earphone jack,
the first terminal of the earphone jack is configured to be connected to the third terminal of the three-electrode plug,
the second terminal of the earphone jack is configured to be connected to the third terminal of the three-electrode plug,
the third terminal of the earphone jack is configured to be connected to the third terminal of the three-electrode plug,
the fourth terminal of the earphone jack is configured to be connected to the second terminal of the three-electrode plug,
the fifth terminal of the earphone jack is configured to be connected to the first terminal of the three-electrode plug, and
the sixth terminal of the earphone jack is configured to be connected to the first terminal of the three-electrode plug.

7. The electronic device according to claim 4, wherein
the earphone jack can be connected further to a four-electrode plug earphone,
the four-electrode plug earphone includes
a first electromagnetic speaker including an input terminal and a ground terminal,
a second electromagnetic speaker including an input terminal and a ground terminal,
a microphone including an output terminal and a ground terminal, and
a four-electrode plug including a first terminal, a second terminal, a third terminal, and a fourth terminal sequentially from a tip end,
the first terminal of the four-electrode plug is configured to be connected to the input terminal of the first electromagnetic speaker,
the second terminal of the four-electrode plug is configured to be connected to the input terminal of the second electromagnetic speaker,
the third terminal of the four-electrode plug is configured to be connected to the ground terminal of the first electromagnetic speaker, the ground terminal of the second electromagnetic speaker, and the ground terminal of the microphone,
the fourth terminal of the four-electrode plug is configured to be connected to the output terminal of the microphone, and
when the four-electrode plug earphone is completely inserted into the earphone jack,
the first terminal of the earphone jack is configured to be connected to the fourth terminal of the four-electrode plug,
the second terminal of the earphone jack is configured to be connected to the third terminal of the four-electrode plug,
the third terminal of the earphone jack is configured to be connected to the third terminal of the four-electrode plug,
the fourth terminal of the earphone jack is configured to be connected to the second terminal of the four-electrode plug,
the fifth terminal of the earphone jack is configured to be connected to the first terminal of the four-electrode plug, and
the sixth terminal of the earphone jack is configured to be connected to the first terminal of the four-electrode plug.

8. The electronic device according to claim 4, wherein
the earphone jack can be connected further to a five-electrode plug earphone of a second type, a three-electrode plug earphone, and a four-electrode plug earphone,
the five-electrode plug earphone of the second type includes
a first differential amplifier configured to include a first input terminal, a second input terminal, a power supply terminal, and a ground terminal and to amplify a difference between a voltage of the first input terminal and a voltage of the second input terminal,
a second differential amplifier configured to include a first input terminal, a second input terminal, a power supply terminal, and a ground terminal and to amplify a difference between a voltage of the first input terminal and a voltage of the second input terminal,
a first piezoelectric element configured to receive a voltage amplified by the first differential amplifier,
a second piezoelectric element configured to receive a voltage amplified by the second differential amplifier,
a microphone including an output terminal and a ground terminal,
a first processor, and
a five-electrode plug including a first terminal, a second terminal, a third terminal, a fourth terminal, and a fifth terminal sequentially from a tip end,
the first terminal of the five-electrode plug is configured to be connected to the first input terminal of the first differential amplifier,
the second terminal of the five-electrode plug is configured to be connected to the first input terminal of the second differential amplifier,
the third terminal of the five-electrode plug is configured to be connected to the power supply terminal of the first differential amplifier, the power supply terminal of the second differential amplifier, and the first processor,
the fourth terminal of the five-electrode plug is configured to be connected to the ground terminal of the first differential amplifier, the ground terminal of the second differential amplifier, the ground terminal of the microphone, the second input terminal of the first differential amplifier, and the second input terminal of the second differential amplifier,
the fifth terminal of the five-electrode plug is configured to be connected to the output terminal of the microphone,
when the five-electrode plug earphone of the second type is completely inserted in the earphone jack,
the first terminal of the earphone jack is configured to be connected to the fifth terminal of the five-electrode plug,
the second terminal of the earphone jack is configured to be connected to the fourth terminal of the five-electrode plug,
the third terminal of the earphone jack is configured to be connected to the third terminal of the five-electrode plug,
the fourth terminal of the earphone jack is configured to be connected to the second terminal of the five-electrode plug,
the fifth terminal of the earphone jack is configured to be connected to the first terminal of the five-electrode plug, and
the sixth terminal of the earphone jack is configured to be connected to the first terminal of the five-electrode plug,
the three-electrode plug earphone includes
a first electromagnetic speaker including an input terminal and a ground terminal,
a second electromagnetic speaker including an input terminal and a ground terminal, and
a three-electrode plug including a first terminal, a second terminal, and a third terminal sequentially from a tip end,
the first terminal of the three-electrode plug is configured to be connected to the input terminal of the first electromagnetic speaker,
the second terminal of the three-electrode plug is configured to be connected to the input terminal of the second electromagnetic speaker,
the third terminal of the three-electrode plug is configured to be connected to the ground terminal of the first electromagnetic speaker and the ground terminal of the second electromagnetic speaker,
when the three-electrode plug earphone is completely inserted in the earphone jack,
the first terminal of the earphone jack is configured to be connected to the third terminal of the three-electrode plug,
the second terminal of the earphone jack is configured to be connected to the third terminal of the three-electrode plug,
the third terminal of the earphone jack is configured to be connected to the third terminal of the three-electrode plug,
the fourth terminal of the earphone jack is configured to be connected to the second terminal of the three-electrode plug,
the fifth terminal of the earphone jack is configured to be connected to the first terminal of the three-electrode plug, and
the sixth terminal of the earphone jack is configured to be connected to the first terminal of the three-electrode plug,
the four-electrode plug earphone includes
a first electromagnetic speaker including an input terminal and a ground terminal,
a second electromagnetic speaker including an input terminal and a ground terminal,
a microphone including an output terminal and a ground terminal, and
a four-electrode plug including a first terminal, a second terminal, a third terminal, and a fourth terminal sequentially from a tip end,
the first terminal of the four-electrode plug is configured to be connected to the input terminal of the first electromagnetic speaker,
the second terminal of the four-electrode plug is configured to be connected to the input terminal of the second electromagnetic speaker,
the third terminal of the four-electrode plug is configured to be connected to the ground terminal of the first electromagnetic speaker, the ground terminal of the second electromagnetic speaker, and the ground terminal of the microphone,
the fourth terminal of the four-electrode plug is configured to be connected to the output terminal of the microphone, and
when the four-electrode plug earphone is completely inserted into the earphone jack,
the first terminal of the earphone jack is configured to be connected to the fourth terminal of the four-electrode plug,
the second terminal of the earphone jack is configured to be connected to the third terminal of the four-electrode plug,
the third terminal of the earphone jack is configured to be connected to the third terminal of the four-electrode plug,
the fourth terminal of the earphone jack is configured to be connected to the second terminal of the four-electrode plug,
the fifth terminal of the earphone jack is configured to be connected to the first terminal of the four-electrode plug, and
the sixth terminal of the earphone jack is configured to be connected to the first terminal of the four-electrode plug.

9. The electronic device according to claim 4, wherein
the five-electrode plug earphone further includes a pulse sensor,
the first processor is configured to control the pulse sensor and to receive a signal from the pulse sensor, and
the third terminal of the five-electrode plug is configured to be connected further to the pulse sensor.

10. The electronic device according to claim 4, wherein
the first terminal, the third terminal, and the fifth terminal are configured to be arranged along a first line in parallel to a direction of insertion over a cylindrical inner wall of the earphone jack, and
the second terminal, the fourth terminal, and the sixth terminal are configured to be arranged along a second line in parallel to the direction of insertion over the cylindrical inner wall of the earphone jack and opposed to the first line.

11. The electronic device according to claim 4, the electronic device further comprising:
a pull-up resistor configured to be connected to a first node on a line between the sixth terminal of the earphone jack and the second processor; and
a pull-down resistor configured to be connected to a second node on a line between the fifth terminal of the earphone jack and the second audio output unit, wherein
the pull-up resistor is higher in resistance value than the pull-down resistor, and
the second processor is configured to determine that the earphone has been inserted into the earphone jack when a voltage of the first node is at a low level.

12. The electronic device according to claim 6, the electronic device further comprising a pull-up resistor configured to be connected to a third node on a line between the first terminal of the earphone jack and the microphone audio processing unit, wherein
the second processor is configured to identify an earphone inserted into the earphone jack as the three-electrode plug earphone when a voltage of the third node is at a low level.

13. The electronic device according to claim 6, the electronic device further comprising:
a pull-up resistor configured to be connected to a third node on a line between the first terminal of the earphone jack and the microphone audio processing unit; and
an inverter configured to receive a voltage of the third node, wherein
the second processor is configured to identify an earphone inserted in the earphone jack as the three-electrode plug earphone when output from the inverter is at a high level.

14. The electronic device according to claim 5, wherein
a fourth node on a line between the fourth terminal of the earphone jack and the first audio output unit is configured to be connected further to the second processor,
the second processor is configured to pull up the fourth node, and
the second processor is configured to identify an earphone inserted in the earphone jack as the five-electrode plug earphone of the first type when a voltage of the fourth node is at a high level.

15. The electronic device according to claim 14, wherein
the second processor is configured to start supply of electric power to the second terminal of the earphone jack from the electric power supply unit after the earphone inserted in the earphone jack has been identified as the five-electrode plug earphone of the first type.

16. The electronic device according to claim 7, the electronic device further comprising a pull-up resistor configured to be connected to a third node on a line between the first terminal of the earphone jack and the microphone audio processing unit, wherein
a fourth node on a line between the fourth terminal of the earphone jack and the first audio output unit is configured to be connected further to the second processor,
a fifth node on a line between the third terminal of the earphone jack and the electric power supply unit is configured to be connected further to the second processor,
the second processor is configured to pull up the fourth node and the fifth node, and
the second processor is configured to identify an earphone inserted in the earphone jack as the four-electrode plug earphone when a voltage of the third node is at a high level, a voltage of the fourth node is at a low level, and a voltage of the fifth node is at the low level.

17. The electronic device according to claim 7, the electronic device further comprising a pull-up resistor configured to be connected to a third node on a line between the first terminal of the earphone jack and the microphone audio processing unit, wherein
a fourth node on a line between the fourth terminal of the earphone jack and the first audio output unit is configured to be connected further to the second processor,
a fifth node on a line between the third terminal of the earphone jack and the electric power supply unit is configured to be connected further to the second processor,
the second processor is configured to pull up the fourth node and the fifth node, and
the second processor is configured to identify an earphone inserted in the earphone jack as a five-electrode plug earphone of a second type when a voltage of the third node is at a high level, a voltage of the fourth node is at a low level, and a voltage of the fifth node is at the high level.

18. The electronic device according to claim 17, wherein
the second processor is configured to start supply of electric power to the second terminal of the earphone jack from the electric power supply unit after the earphone inserted in the earphone jack has been identified as the five-electrode plug earphone of the second type.

19. The electronic device according to claim 15, wherein
when the first terminal of the five-electrode plug is connected to the fifth terminal and the sixth terminal of the earphone jack during a process of insertion of the five-electrode plug earphone of the first type or the five-electrode plug earphone of the second type into the earphone jack, the third terminal of the five-electrode plug is configured not to be connected to the second terminal of the earphone jack.

20. An electronic device system comprising:
a five-electrode plug earphone; and
an electronic device,
the five-electrode plug earphone including
a first electromagnetic speaker including an input terminal and a ground terminal,
a second electromagnetic speaker including an input terminal and a ground terminal,
a microphone including an output terminal and a ground terminal,
a first processor, and
a five-electrode plug including a first terminal, a second terminal, a third terminal, a fourth terminal, and a fifth terminal sequentially from a tip end,
the first terminal of the five-electrode plug being configured to be connected to the input terminal of the first electromagnetic speaker,
the second terminal of the five-electrode plug being configured to be connected to the input terminal of the second electromagnetic speaker,
the third terminal of the five-electrode plug being configured to be connected to the first processor,
the fourth terminal of the five-electrode plug being configured to be connected to the ground terminal of the first electromagnetic speaker, the ground terminal of the second electromagnetic speaker, and the ground terminal of the microphone, and
the fifth terminal of the five-electrode plug being configured to be connected to the output terminal of the microphone, and
the electronic device including
an earphone jack which can be connected to the five-electrode plug earphone, the earphone jack including a first terminal, a second terminal, a third terminal, a fourth terminal, a fifth terminal, and a sixth terminal in an order of proximity to an insertion port,
a microphone audio processing unit configured to be connected to the first terminal of the earphone jack,
a ground power supply configured to be connected to the second terminal of the earphone jack,
an electric power supply unit configured to be connected to the third terminal of the earphone jack,
a first audio output unit configured to be connected to the fourth terminal of the earphone jack,
a second audio output unit configured to be connected to the fifth terminal of the earphone jack, and
a second processor configured to be connected to the sixth terminal of the earphone jack and configured to determine insertion of the five-electrode plug into the earphone jack.
